(19) United States
(12) Patent Application Publication
(10) Pub. No.: US 2025/0385109 A1
(43) Pub. Date: Dec. 18, 2025

(54) SEMICONDUCTOR MANUFACTURING APPARATUS INCLUDING BONDING HEAD

(71) Applicant: Samsung Electronics Co., Ltd., Suwon-si (KR)

(72) Inventors: Junhyung KIM, Suwon-si (KR); Mok SHIN, Suwon-si (KR); Seonmin YUN, Suwon-si (KR)

(73) Assignee: Samsung Electronics Co., Ltd., Suwon-si (KR)

(21) Appl. No.: 19/016,484

(22) Filed: Jan. 10, 2025

(30) Foreign Application Priority Data
Jun. 17, 2024 (KR) 10-2024-0078470

(51) Int. Cl. H01L 21/67

(52) U.S. Cl. CPC H01L 21/67144

(57) ABSTRACT

A semiconductor manufacturing apparatus configured to bond a semiconductor chip to a substrate includes a bonding head configured to transfer the semiconductor chip such that the semiconductor chip is stacked on the substrate, the bonding head including an attachment pad configured to attach the semiconductor chip thereto and a vertical movement actuator configured to lower the attachment pad such that a portion of an edge of the semiconductor chip comes into contact with a top surface of the substrate. The attachment pad is configured to rotate around an axis passing through the portion of the edge of the semiconductor chip in contact with the substrate.

### CROSS-REFERENCE TO RELATED APPLICATION

This application is based on and claims priority under 35 U.S.C. § 119 to Korean Patent Application No. 10-2024-0078470, filed on Jun. 17, 2024, in the Korean Intellectual Property Office, the disclosure of which is incorporated by reference herein in its entirety.

### BACKGROUND

The inventive concepts relate to semiconductor manufacturing apparatuses, and more particularly, to semiconductor manufacturing apparatuses including a bonding head for a chip bonding process.

Semiconductor devices having a stack structure of semiconductor chips may be beneficial for increasing the mounting density of semiconductor chips, for reducing the length of electrical connection paths between semiconductor chips, and/or for higher-speed signal processing. To manufacture a semiconductor device having a stack structure of semiconductor chips, a method of stacking semiconductor chips by arranging a film including an adhesive component between the semiconductor chips may be used. However, a direct bonding method by which semiconductor chips are directly bonded to each other without a separate adhesive medium may also be used.

### SUMMARY

Some example embodiments of the inventive concepts provide bonding heads for a chip bonding process and/or semiconductor manufacturing apparatuses including the bonding head.

Also, the problems to be solved by the technical ideas of the present inventive concepts are not limited to those mentioned herein, and the inventive concepts can be clearly understood by those skilled in the art from the description below.

According to an example embodiment of the inventive concepts, there is provided a semiconductor manufacturing apparatus configured to bond a semiconductor chip to a substrate. The semiconductor manufacturing apparatus includes a bonding head configured to transfer the semiconductor chip such that the semiconductor chip is stacked on the substrate, the bonding head including an attachment pad configured to attach the semiconductor chip thereto and a vertical movement actuator configured to lower the attachment pad such that a portion of an edge of the semiconductor chip comes into contact with a top surface of the substrate, wherein the attachment pad is configured to rotate around an axis that passes through the portion of the edge of the semiconductor chip in contact with the substrate.

According to an example embodiment of the inventive concepts, there is provided a semiconductor manufacturing apparatus configured to bond a semiconductor chip to a substrate. The semiconductor manufacturing apparatus includes a bonding head configured to transfer the semiconductor chip such that the semiconductor chip is stacked on the substrate, the bonding head including an attachment pad configured to attach the semiconductor chip thereto, wherein the attachment pad includes a lower body configured to attach the semiconductor chip thereto, an upper body including a space configured to accommodate the lower body, and a parallel rotation actuator in the space and connected to the lower body and the upper body, the parallel rotation actuator configured to rotate the lower body with respect to the upper body, which is stationary, by changing a length of the parallel rotation actuator in a lateral direction.

According to an example embodiment of the inventive concepts, a semiconductor manufacturing apparatus includes a loading stage configured to load a ring frame having a semiconductor chip mounted thereon, a loading/unloading stage configured to load a substrate thereon and unloaded the substrate therefrom, a chip separation stage configured to reducing adhesive strength of an adhesive film of the ring frame supporting the semiconductor chip, a bonding stage configured to perform a bonding process on the substrate and the semiconductor chip, the bonding stage including a support and a bonding head, the support including a main surface on which the substrate is to be mounted, the bonding head configured to stack the semiconductor chip on the substrate mounted on the support, and a chip transport module configured to transport the semiconductor chip from the chip separation stage toward the bonding head, wherein the bonding head includes an attachment pad configured to attach the semiconductor chip thereto and a vertical movement actuator configured to lower the attachment pad such that a portion of an edge of the semiconductor chip comes into contact with a top surface of the substrate, and wherein the attachment pad is configured to rotate around an axis passing through the portion of the edge of the semiconductor chip in contact with the substrate until a bottom surface of the semiconductor chip attached to the attachment pad contacts an entirety of the top surface of the substrate.

### BRIEF DESCRIPTION OF THE DRAWINGS

Some example embodiments will be more clearly understood from the following detailed description taken in conjunction with the accompanying drawings in which:

FIG. 1 is a cross-sectional view illustrating a bonding head according to an example embodiment;

FIG. 2 is a cross-sectional view illustrating a bonding head according to an example embodiment;

FIG. 3 is a conceptual diagram illustrating Z-axis rotation of a semiconductor chip by the bonding head of FIG. 1;

FIG. 4 is a conceptual diagram illustrating Y-axis rotation of a semiconductor chip by the bonding head of FIG. 1;

FIG. 5 is a flowchart of a method of controlling a bonding head, according to an example embodiment;

FIGS. 6A to 6J are cross-sectional views and plan views illustrating a method of controlling a bonding head, according to an example embodiment;

FIG. 7 is a cross-sectional view illustrating a bonding head according to an example embodiment;

FIGS. 8A to 8E are cross-sectional views illustrating a method of controlling a bonding head, according to an example embodiment;

FIG. 9 is a cross-sectional view illustrating a bonding head according to an example embodiment;

FIGS. 10A to 10G are cross-sectional views illustrating a method of controlling a bonding head, according to an example embodiment;

FIG. 11 is a cross-sectional view illustrating a bonding head according to an example embodiment;

FIG. 12 is a flowchart of a method of controlling a bonding head, according to an example embodiment;

FIGS. 13A to 13E are cross-sectional views illustrating a method of controlling a bonding head, according an example embodiment;

FIGS. 14A to 14C are cross-sectional views illustrating a method of controlling a bonding head, according to an example embodiment;

FIG. 15 is a schematic diagram of the configuration of a semiconductor manufacturing apparatus according to an example embodiment;

FIG. 16 is a flowchart of a semiconductor manufacturing method using the semiconductor manufacturing apparatus of FIG. 15;

FIG. 17 is a cross-sectional view of a ring frame on which semiconductor chips are mounted;

FIGS. 18A to 18C are conceptual diagrams illustrating a chip separation process performed by a chip separation stage of a bonding module, according to an example embodiment;

FIGS. 19A to 19C are conceptual diagrams illustrating a process of transporting a semiconductor chip by using a chip transport module of a bonding module, according to an example embodiment;

FIG. 20 is a conceptual diagram illustrating a process of detecting a position of a semiconductor chip, which is attached to a bonding head, by using a first imaging device, according to an example embodiment;

FIG. 21 is a conceptual diagram illustrating a process of detecting a position of a substrate by using a second imaging device, according to an example embodiment;

FIG. 22 is a flowchart of a chip-substrate bonding method using the semiconductor manufacturing apparatus of FIG. 15, according to an example embodiment;

FIG. 23 is a block diagram of a bonding module according to an embodiment;

FIGS. 24A to 24E are conceptual diagrams illustrating the chip-substrate bonding method using the semiconductor manufacturing apparatus of FIG. 15;

FIG. 25 is a flowchart of a semiconductor manufacturing method according to an example embodiment; and

FIG. 26 is a cross-sectional view of a bonded structure in which a semiconductor chip is bonded to a substrate.

### DETAILED DESCRIPTION

Hereinafter, some example embodiments are described in detail with reference to the accompanying drawings. However, the inventive concepts should not be construed as being limited to the disclosed example embodiments and may be embodied in other various forms. The disclosed example embodiments are provided to fully convey the scope of the inventive concepts to those skilled in the art rather than to allow the inventive concepts to be fully completed.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

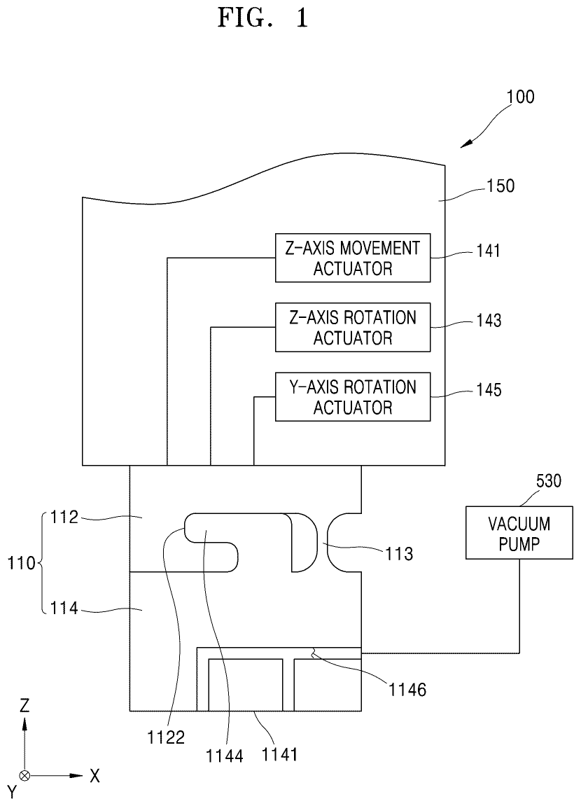

FIG. 1 is a cross-sectional view illustrating a bonding head 100 according to an example embodiment.

The bonding head 100 may be provided in a bonding module for performing a bonding process on a semiconductor chip and a substrate. The bonding head 100 may transfer a semiconductor chip so that the semiconductor chip is stacked on a substrate. The bonding head 100 may be provided in a bonding module configured to perform a die-to-wafer bonding process that bonds a semiconductor chip to a substrate without a separate adhesive medium. However, application examples of the bonding head 100 are not limited to those mentioned above. For example, the bonding head 100 may be provided in a bonding module configured to perform a wafer-to-wafer bonding process that bonds two wafers to each other and a chip-to-chip bonding process that bonds two chips to each other.

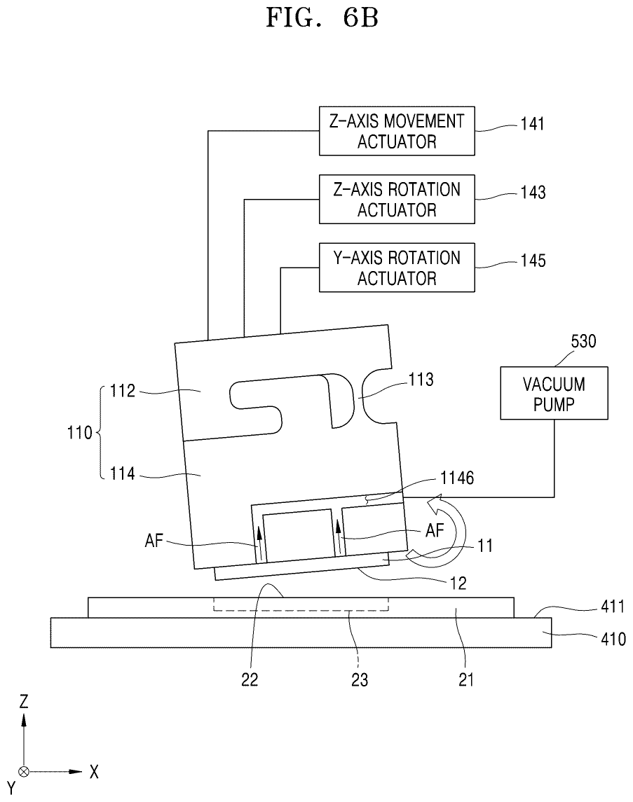

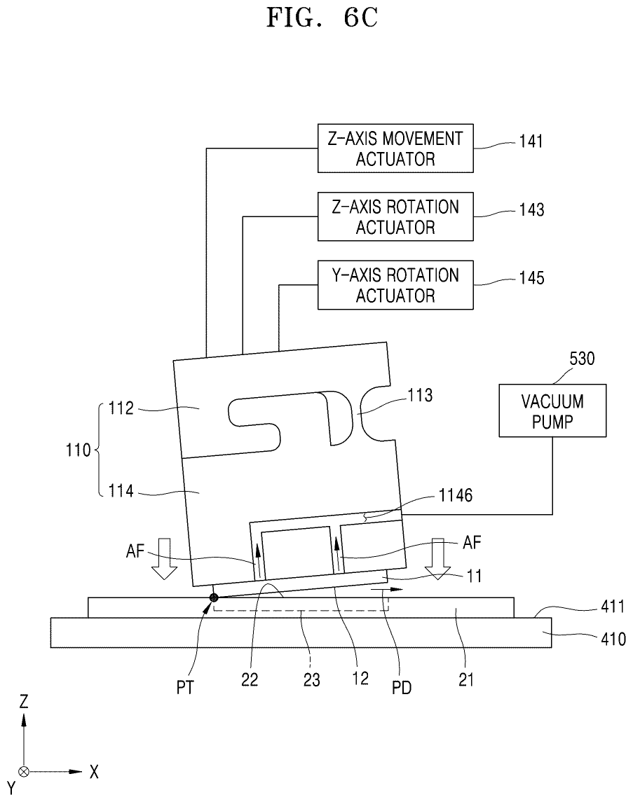

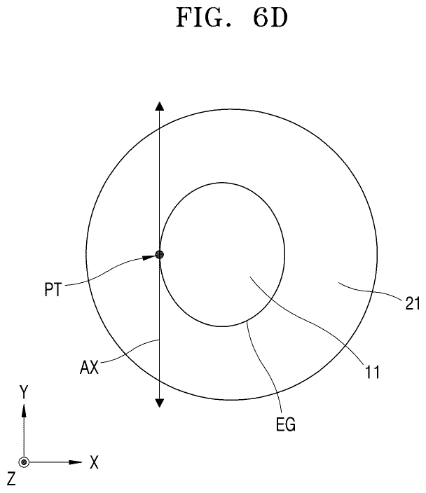

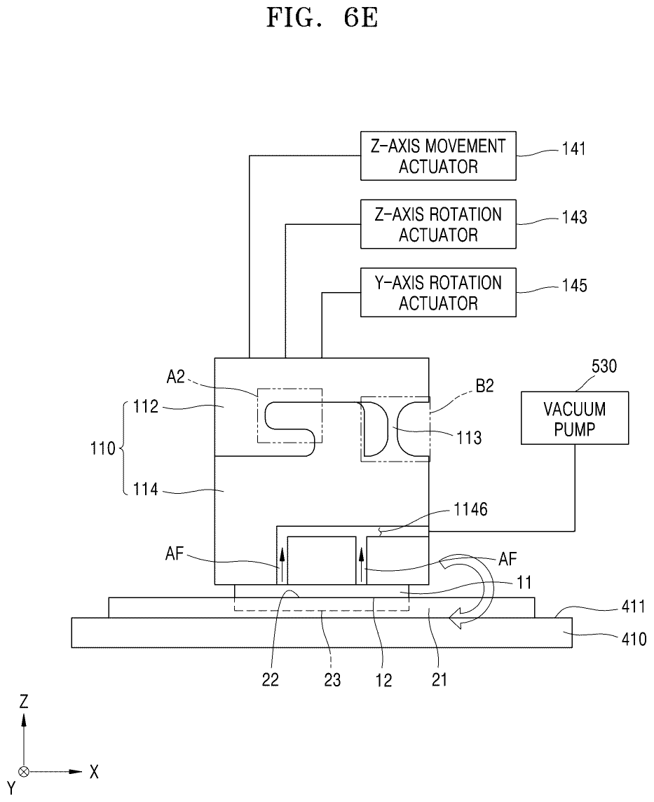

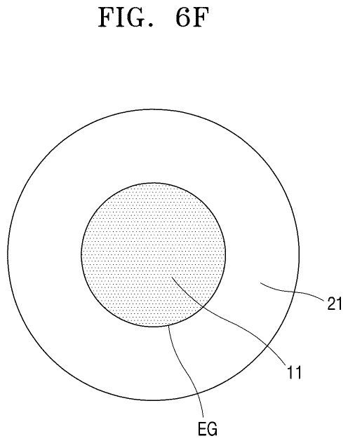

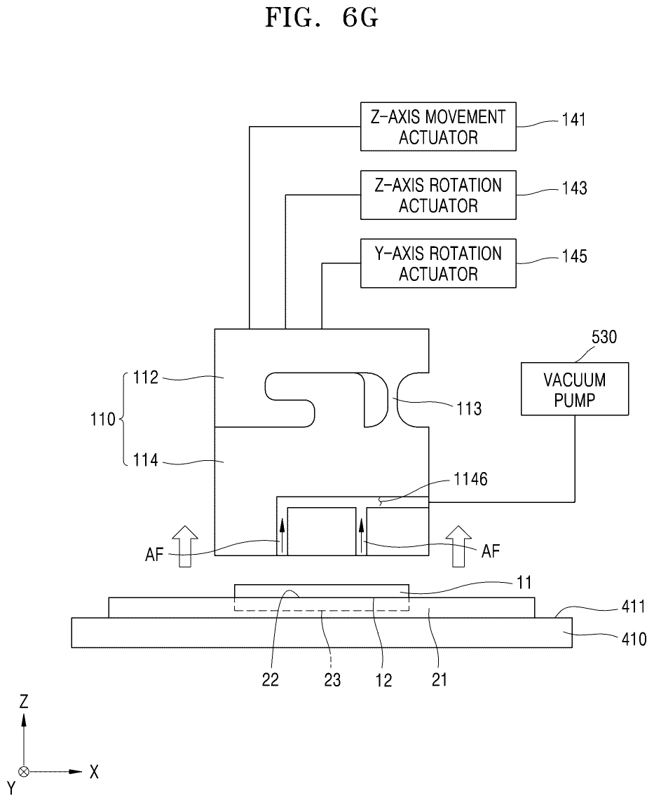

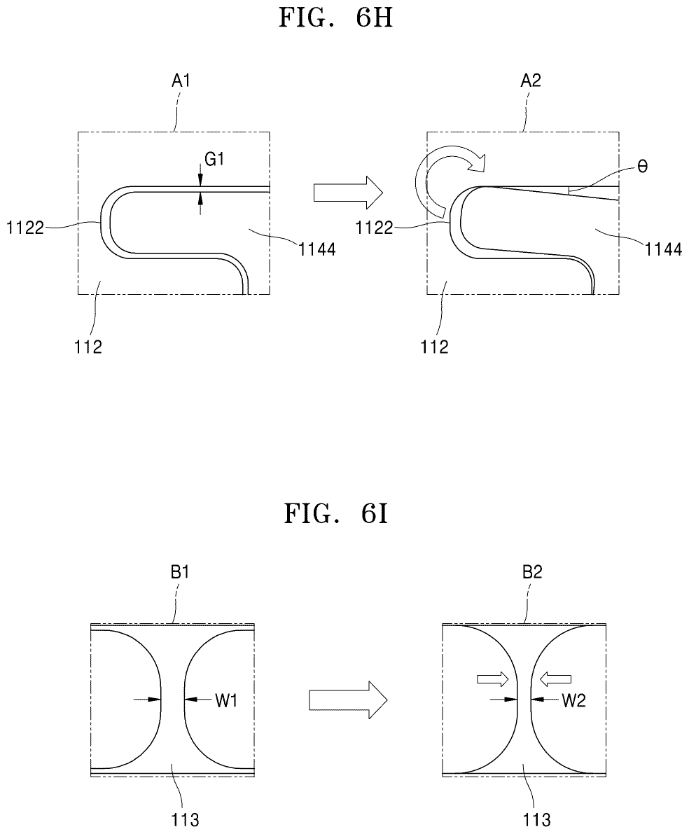

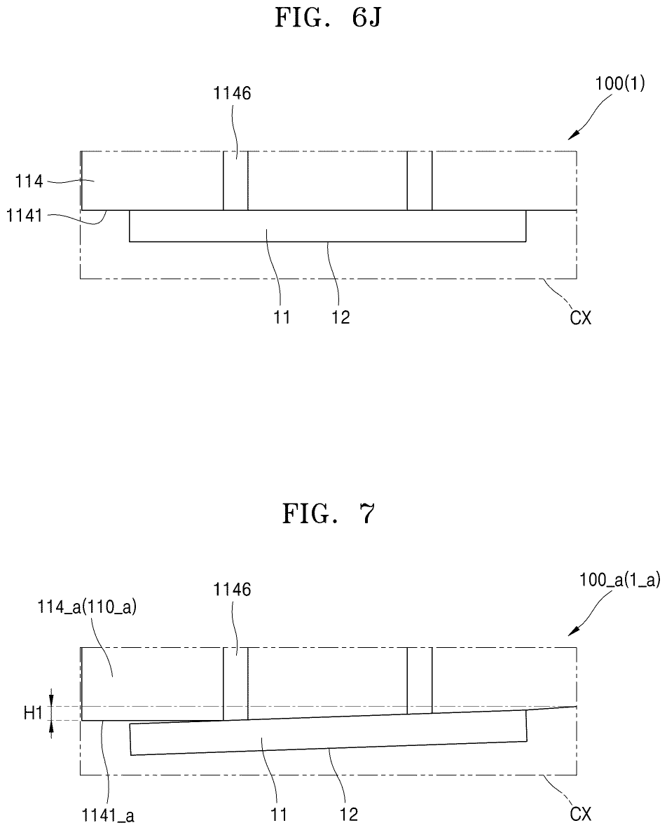

Here, a direction in which the bonding head 100 moves up and down may be defined as a vertical direction (a Z direction). The vertical direction (the Z direction) may be defined as being perpendicular to a main surface 411 (see FIG. 6A) of a support 410 (see FIG. 6A), on which a substrate 21 (see FIG. 6A) is mounted, when the support 410 is not inclined. The vertical direction (the Z direction) may be orthogonal to a first horizontal direction (an X direction) and a second horizontal direction (a Y direction). As described in detail below, a direction parallel with an axis around which the bonding head 100 rotates may be defined as the second horizontal direction (the Y direction).

The bonding head 100 may include an attachment pad 110 including an upper body 112 and a lower body 114. The attachment pad 110 may have a pillar shape or a hexahedral shape. The lower body 114 may include a bottom surface 1141 to which a semiconductor chip 11 (see FIG. 6A) (e.g., a bonding target) is attached.

In some example embodiments, the bonding head 100 may be configured to vacuum-adsorb the semiconductor chip 11. For example, the bonding head 100 may include a vacuum passage 1146 connected to a vacuum pump 530. The vacuum passage 1146 may be exposed by the bottom surface 1141 of the lower body 114. An end of the vacuum passage 1146 may be located on a sidewall of a lower end portion of the lower body 114.

When the attachment pad 110 is in contact with or adjacent to a surface of the semiconductor chip 11, the vacuum pump 530 may apply vacuum pressure to the vacuum passage 1146 such that the semiconductor chip 11 is vacuum-adsorbed onto the lower body 114 of the attachment pad 110. For example, when the vacuum pump 530 applies vacuum pressure to the vacuum passage 1146, a pressure lower than the surrounding pressure of the semiconductor chip 11 may be formed on a surface of the semiconductor chip 11, and accordingly, the semiconductor chip 11 may be vacuum-adsorbed onto the lower body 114 of the attachment pad 110. The vacuum pump 530 may also release or terminate the vacuum pressure in the vacuum passage 1146, thereby allowing the semiconductor chip 11 to be detached from the attachment pad 110.

In some example embodiments, the bonding head 100 may be configured to support the semiconductor chip 11 by using an electrostatic force or support the semiconductor chip 11 in a mechanical manner.

According to an example embodiment, the upper body 112 of the attachment pad 110 may be on the lower body 114 of the attachment pad 110, and a sidewall of the lower body 114 and a sidewall of the upper body 112 may form a straight line. The upper body 112 of the attachment pad 110 may include a groove 1122 in a lower portion of the upper body 112. The lower body 114 of the attachment pad 110 may include a stopper 1144 protruding in a horizontal direction (the X direction and/or the Y direction). The groove 1122 may be recessed in the horizontal direction (the X direction and/or the Y direction) in the upper body 112, and the stopper 1144 may be inserted into the groove 1122. As the stopper 1144 is inserted into the groove 1122 of the upper body 112, the upper body 112 may engage with the lower body 114. However, the stopper 1144 may not be in contact with the upper body 112, as described below.

According to an example embodiment, the attachment pad 110 may further include an elastic hinge 113 separated from the stopper 1144 in the horizontal direction (the X direction and/or the Y direction). The elastic hinge 113 may have a shape of which the width decreases toward the center of the elastic hinge 113 in the vertical direction (the Z direction). The elastic hinge 113 may connect the upper body 112 of the attachment pad 110 to the lower body 114 of the attachment pad 110. The upper body 112 and the lower body 114 may integrally form a single body through the elastic hinge 113. As described below, when the lower body 114 rotates, the elastic hinge 113 may reduce or prevent a rapid rotation by using an elastic force, thereby reducing or preventing slippage of the semiconductor chip 11.

In some example embodiments, a horizontal width of the attachment pad 110 in the horizontal direction (the X direction or the Y direction) may be about 50% to about 150% of a horizontal width of the semiconductor chip 11 in the horizontal direction (the X direction or the Y direction). For example, when the horizontal width of the semiconductor chip 11 is 10 mm, the horizontal width of the attachment pad 110 may be about 5 mm to about 15 mm.

In some example embodiments, the attachment pad 110 may have a horizontal width less than the horizontal width of the semiconductor chip 11. In this case, to allow the semiconductor chip 11 to be stably supported by the attachment pad 110, the bonding head 100 may be located such that the center of the semiconductor chip 11 is aligned with the center of the bottom surface 1141 of the lower body 114 and may vacuum-adsorb the semiconductor chip 11.

The attachment pad 110 may include a material of which the shape may be changed by an external force. For example, the attachment pad 110 may include silicon, rubber, ceramic, metal or a combination thereof. In some example embodiments, the attachment pad 110 may include silicon rubber.

In some example embodiments, the bonding head 100 may further include a Z-axis movement actuator 141 for the up-and-down movement of the attachment pad 110. The Z-axis movement actuator 141 may move the attachment pad 110 up and down in the vertical direction (the Z direction), thereby adjusting the position of the attachment pad 110 in the vertical direction (the Z direction). Here, the vertical direction (the Z direction) may be defined as being perpendicular to the main surface 411 (see FIG. 6A) of the support 410 (see FIG. 6A), on which the substrate 21 (see FIG. 6A) is mounted. The Z-axis movement actuator 141 may move the attachment pad 110, to which the semiconductor chip 11 is attached, up and down such that a pick-and-place operation may be performed on the semiconductor chip 11. The Z-axis movement actuator 141 may be configured to apply an appropriate pressure to the semiconductor chip 11 during bonding between the semiconductor chip 11 and the substrate 21. The Z-axis movement actuator 141 may include a motor, a hydraulic cylinder, a pneumatic cylinder, and the like.

A bonding process using the bonding head 100 may be controlled by a controller of a bonding module. The controller may be implemented by hardware, firmware, software, or a combination thereof. For example, the controller may include a computing device, such as a workstation computer, a desktop computer, a laptop computer, or a tablet computer. For example, the controller may include a memory device, such as read-only memory (ROM) or random-access memory (RAM), and a processor, e.g., a microprocessor, a central processing unit (CPU), or a graphics processing unit (GPU), which is configured to perform certain operations and algorithms. The controller may include a receiver and a transmitter to receive and transmit electrical signals.

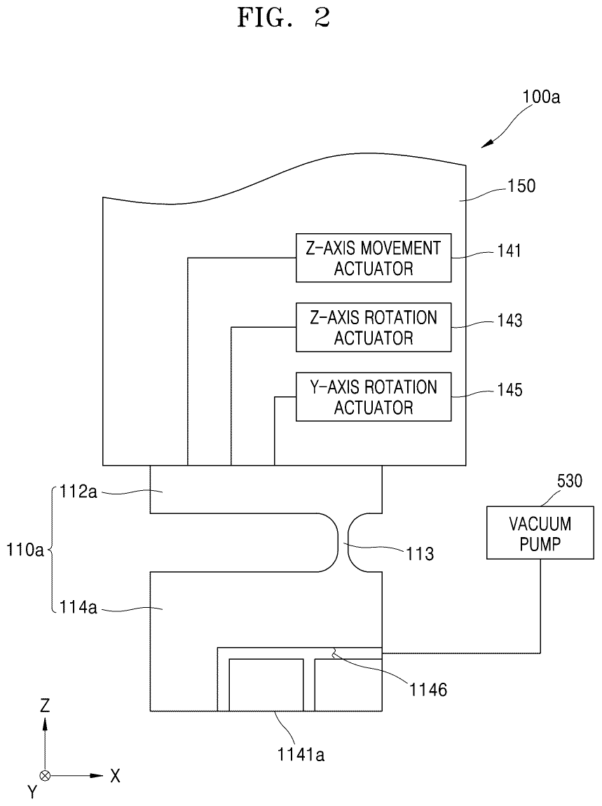

FIG. 2 is a cross-sectional view illustrating a bonding head 100a according to some example embodiments.

The bonding head 100a of FIG. 2 is the same as or substantially similar to the bonding head 100 of FIG. 1, except for the shape of an attachment pad 110a. Therefore, descriptions of elements mentioned with respect to FIG. 1 are omitted below.

The bonding head 100a may include an attachment pad 110a, which includes an upper body 112a and a lower body 114a. The attachment pad 110a may have a pillar shape or a hexahedral shape. The lower body 114a may include a bottom surface 1141a to which the semiconductor chip 11 (see FIG. 6A) (e.g., a bonding target) is attached.

Unlike the upper body 112 in FIG. 1, the upper body 112a in FIG. 2 may not include a groove (1122 in FIG. 1). Unlike the lower body 114 in FIG. 1, the lower body 114a in FIG. 2 may not include a stopper (1144 in FIG. 1). Accordingly, the upper body 112a may be connected to the lower body 114a by the elastic hinge 113, and empty space may be formed in a lateral direction (the X direction and/or the Y direction) of the elastic hinge 113.

Because the attachment pad 110a in FIG. 2 does not include a stopper, a difference in rotation angle between the upper body 112a and the lower body 114a may increase when the attachment pad 110a rotates around an axis in the second horizontal direction (the Y direction), which is described below.

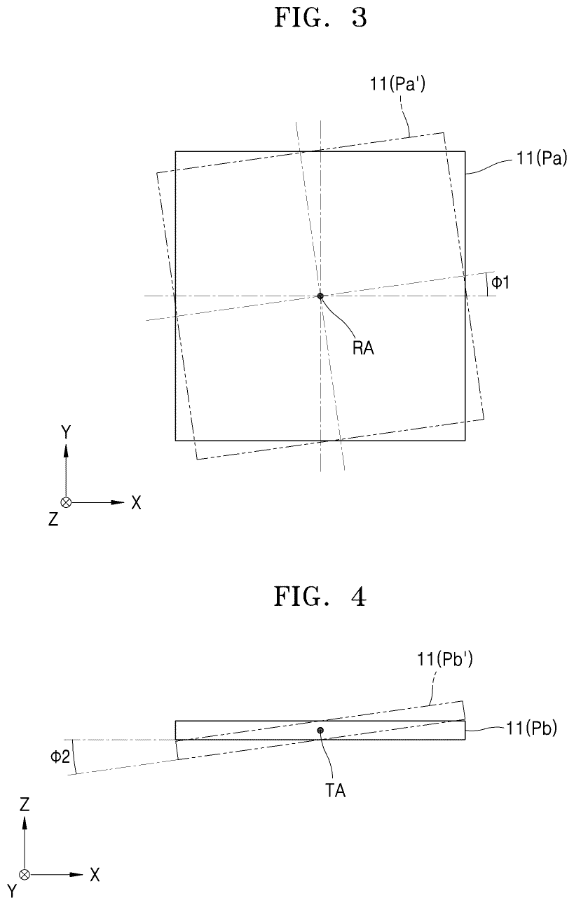

FIG. 3 is a conceptual diagram illustrating Z-axis rotation of a semiconductor chip by the bonding head 100 of FIG. 1.

In FIG. 3, reference numeral “11 (Pa)” denotes the semiconductor chip 11 at a first position (or a reference position) in the rotation direction and reference numeral “11 (Pa′)” denotes the semiconductor chip 11 at a second position in the rotation direction.

Referring to FIGS. 1 and 3, the bonding head 100 may include a Z-axis rotation actuator 143 for the rotation of the attachment pad 110. The Z-axis rotation actuator 143 may rotate the semiconductor chip 11 attached to the attachment pad 110 by using the vertical direction (the Z direction) as a rotation axis RA, thereby adjusting the position of the semiconductor chip 11 in the rotation direction. The position of the semiconductor chip 11 in the rotation direction may refer to a rotation angle § 1, by which the semiconductor chip 11 rotates from the reference position by using the vertical direction (the Z direction) as the rotation axis RA on an X-Y plane that is parallel with the main surface 411 (see FIG. 6A) of the support 410 (see FIG. 6A) on which the substrate 21 (see FIG. 6A) is mounted.

The Z-axis rotation actuator 143 may rotates the attachment pad 110 by using the vertical direction (the Z direction) as the rotation axis RA. In other words, the Z-axis rotation actuator 143 may be configured to rotate the attachment pad 110, to which the semiconductor chip 11 is attached, on the X-Y plane parallel with the main surface 411 of the support 410 on which the substrate 21 is mounted. Before the bonding between the semiconductor chip 11 and the substrate 21 begins, the Z-axis rotation actuator 143 may rotate the attachment pad 110 to align the semiconductor chip 11 with the substrate 21 in the rotation direction. The Z-axis rotation actuator 143 may include a rotary motor.

FIG. 4 is a conceptual diagram illustrating Y-axis rotation of a semiconductor chip by the bonding head 100 of FIG. 1.

In FIG. 4, reference numeral “11(Pb)” denotes the semiconductor chip 11 at a first position (or a reference position) in the rotation direction and reference numeral “11(Pb′)” denotes the semiconductor chip 11 at a second position in the rotation direction.

Referring to FIGS. 1 and 4, the bonding head 100 may include a Y-axis rotation actuator 145 for the rotation of the attachment pad 110. The Y-axis rotation actuator 145 may rotate the semiconductor chip 11 attached to the attachment pad 110 by using a direction (e.g., the X direction or the Y direction), which is parallel with the main surface 411 (see FIG. 6A) of the support 410 (see FIG. 6A) on which the substrate 21 (see FIG. 6A) is mounted, as a rotation axis TA, thereby adjusting the position of the semiconductor chip 11 in the rotation direction. For example, the position of the semiconductor chip 11 in the rotation direction may refer to a rotation angle ϕ2, by which a bonding surface 12 (see FIG. 6A) of the semiconductor chip 11 rotates from the reference position by using the direction (e.g., the X direction or the Y direction), which is parallel with the main surface 411 of the support 410, as the rotation axis TA.

The Y-axis rotation actuator 145 may rotates the attachment pad 110 by using the direction parallel with the main surface 411 of the support 410 as the rotation axis TA. For example, the attachment pad 110 may be rotatably mounted on a frame 150 of the bonding head 100, and the Y-axis rotation actuator 145 may rotate the attachment pad 110. Before the bonding between the semiconductor chip 11 and the substrate 21 begins, the Y-axis rotation actuator 145 may tilt the attachment pad 110 such that the bonding surface 12 of the semiconductor chip 11 is parallel with a bonding surface 22 (see FIG. 6A) of the substrate 21. In some example embodiments, before the bonding between the semiconductor chip 11 and the substrate 21 begins, the Y-axis rotation actuator 145 may rotate the attachment pad 110 such that the angle between the bonding surface 12 of the semiconductor chip 11 and the bonding surface 22 of the substrate 21 has a certain value (e.g., about 0.5 degrees to about 15 degrees). The Y-axis rotation actuator 145 may include a motor, a hydraulic cylinder, a pneumatic cylinder, and the like.

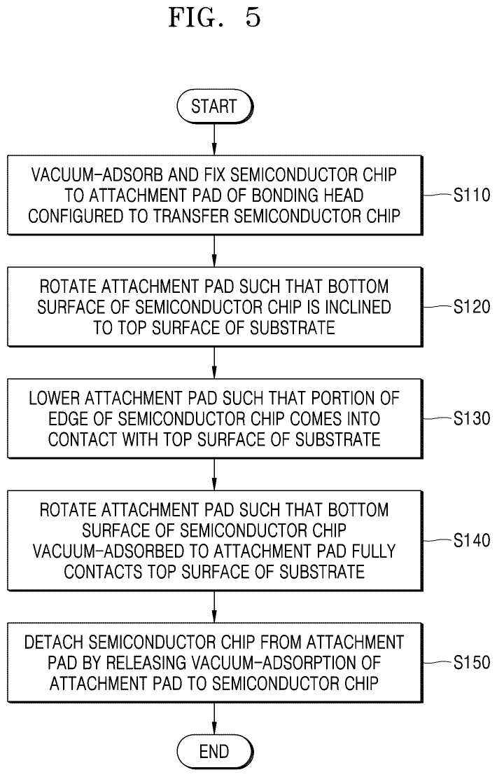

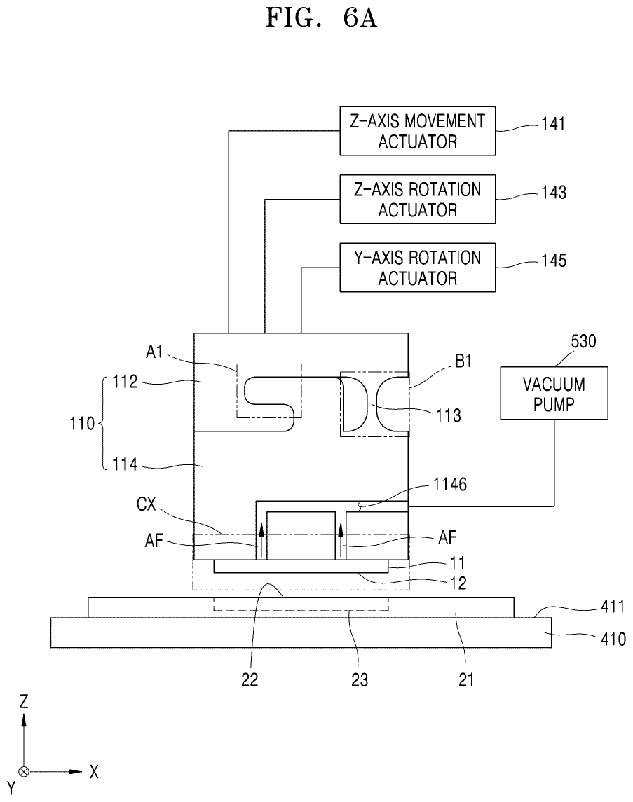

FIG. 5 is a flowchart of a method of controlling the bonding head 100, according to an example embodiment. FIGS. 6A to 6J are cross-sectional views and plan views illustrating a method of controlling the bonding head 100, according to an example embodiment. The method of controlling the bonding head 100 is described in detail with reference to FIG. 5 and FIGS. 6A to 6J below.

Referring to FIGS. 5 and 6A, to stack the semiconductor chip 11 on the substrate 21, the method of controlling the bonding head 100 may include vacuum-adsorbing and fixing the semiconductor chip 11 onto the attachment pad 110 of the bonding head 100, which is configured to transfer the semiconductor chip 11, in operation S110.

According to an example embodiment, the bonding head 100 may fix the semiconductor chip 11 to the bottom surface 1141 of the lower body 114. The bonding head 100 may adjust the position of the attachment pad 110 in the vertical direction (the Z direction) such that the bottom surface 1141 of the lower body 114 is in contact with or adjacent to a surface of the semiconductor chip 11 and may then vacuum-adsorb the semiconductor chip 11 by using the vacuum pump 530. When the vacuum pump 530 applies vacuum pressure to the vacuum passage 1146, an adsorption force AF for vacuum-adsorbing the semiconductor chip 11 may be applied to the semiconductor chip 11 through the vacuum passage 1146.

The attachment pad 110 may support the semiconductor chip 11 such that the bonding surface 12 of the semiconductor chip 11 faces downwards and a surface of the semiconductor chip 11 opposite to the bonding surface 12 of the semiconductor chip 11 is in contact with the bottom surface 1141 of the lower body 114.

Referring to FIGS. 5 and 6B, the method of controlling the bonding head 100 may include rotating the attachment pad 110 such that the bottom surface of the semiconductor chip 11 is inclined to the top surface of the substrate 21 in operation S120.

The bonding head 100 may position the attachment pad 110 such that the semiconductor chip 11 is aligned with a chip 23 of the substrate 21 in the vertical direction (the Z direction) and then rotate the attachment pad 110 by using the Y-axis rotation actuator 145. The Y-axis rotation actuator 145 may rotate the attachment pad 110 by using the second horizontal direction (the Y direction), which is parallel with the main surface 411 of the support 410 on which the substrate 21 is mounted, as a rotation axis. The Y-axis rotation actuator 145 may rotate the attachment pad 110 such that the bonding surface 12 (e.g., the bottom surface) of the semiconductor chip 11 attached to the attachment pad 110 is inclined to the bonding surface 22 (e.g., the top surface) of the substrate 21. For example, the attachment pad 110 may be rotated such that the angle between the bonding surface 12 of the semiconductor chip 11 and the bonding surface 22 of the substrate 21 is about 0.5 degrees to about 12 degrees. However, the numerical value of the angle described above is just an example, and the inventive concepts are not limited thereto. At this time, the upper body 112 and the lower body 114 may integrally rotate by the same angle.

FIG. 6D is a plan view of the substrate 21 in FIG. 6C and the semiconductor chip 11 aligned on the substrate 21 in FIG. 6C, as viewed in the vertical direction (the Z direction).

Referring to FIGS. 5, 6C, and 6D, the method of controlling the bonding head 100 may include lowering the attachment pad 110 such that a portion of an edge EG of the semiconductor chip 11 comes into contact with the bonding surface 22 of the substrate 21 in operation S130. When the semiconductor chip 11 is rotated and a portion of the edge EG of the semiconductor chip 11, which is closest to the bonding surface 22 of the substrate 21, is referred to as a first edge, the bonding head 100 may allow the first edge of the bonding surface 12 of the semiconductor chip 11 to contact the bonding surface 22 of the substrate 21. For example, the bonding head 100 may adjust the position of the attachment pad 110 in the vertical direction (the Z direction) such that the first edge of the bonding surface 12 of the semiconductor chip 11 comes into contact with the bonding surface 22 of the substrate 21. When the first edge of the bonding surface 12 of the semiconductor chip 11 comes into contact with the bonding surface 22 of the substrate 21, a point at which the first edge of the bonding surface 12 of the semiconductor chip 11 contacts the bonding surface 22 of the substrate 21 may be defined as a point PT. In this case, an axis which extends in the second horizontal direction (the Y direction) through the point PT may be defined as a rotation axis AX.

FIG. 6F is a plan view of the substrate 21 in FIG. 6E and the semiconductor chip 11 aligned on the substrate 21 in FIG. 6E, as viewed in the vertical direction (the Z direction).

Referring to FIGS. 5, 6E, and 6F, the method of controlling the bonding head 100 may include controlling the attachment pad 110 such that the bottom surface of the semiconductor chip 11 vacuum-adsorbed to the attachment pad 110 fully contacts the top surface of the substrate 21 in operation S140. The bonding head 100 may move the attachment pad 110 toward the support 410 in the vertical direction (the Z direction) by using the Z-axis movement actuator 141. At this time, the attachment pad 110 may rotate clockwise with respect to the rotation axis AX in FIG. 6D. As the attachment pad 110 rotates with respect to the rotation axis AX, bonding may begin from a portion where the first edge of the bonding surface 12 of the semiconductor chip 11 contacts the bonding surface 22 of the substrate 21. The bonding between the semiconductor chip 11 and the substrate 21 may spread in a spread direction PD from the first edge of the bonding surface 12 of the semiconductor chip 11 toward a second edge of the bonding surface 12 of the semiconductor chip 11, which is opposite to the first edge.

According to an example embodiment, the attachment pad 110 may rotate with respect the rotation axis AX in FIG. 6D such that the bonding surface 12 of the semiconductor chip 11 attached to the attachment pad 110 fully contacts the bonding surface 22 of the substrate 21. As shown in FIG. 6E, when the semiconductor chip 11 fully contacts the substrate 21, the Z-axis movement actuator 141 may stop driving vertical movement.

Referring to FIGS. 5 and 6G, the method of controlling the bonding head 100 may include detaching the semiconductor chip 11 from the attachment pad 110 by releasing the vacuum-adsorption of the attachment pad 110 to the semiconductor chip 11 in operation S150. When the bonding between the semiconductor chip 11 and the substrate 21 is completed, the vacuum pump 530 may stop applying vacuum pressure to the vacuum passage 1146. Thereafter, the Z-axis movement actuator 141 may move the bonding head 100 upwards away from the support 410.

FIG. 6H is an enlarged view of a region A1 in FIG. 6A and a region A2 in FIG. 6E. In detail, FIG. 6A is a cross-sectional view of the bonding head 100 before the semiconductor chip 11 attached to the attachment pad 110 contacts the substrate 21, and FIG. 6E is a cross-sectional view of the bonding head 100 after the semiconductor chip 11 attached to the attachment pad 110 fully contacts the substrate 21.

As shown in the region A1, before the semiconductor chip 11 contacts the substrate 21, the stopper 1144 inserted into the groove 1122 may be spaced apart from the upper body 112 without contact. In this case, the distance between the stopper 1144 inserted into the groove 1122 and the upper body 112 may be defined as a first gap G1. According to an example embodiment, the first gap G1 may be about 10 μm to about 99 μm.

As shown in the region A2, when the attachment pad 110 rotates with respect to the rotation axis AX in FIG. 6D, the elastic hinge 113 may be deformed, and thus, the rotation angle of the upper body 112 may be different from the rotation angle of the lower body 114. In this case, because there is an empty space between the substrate 21 and the semiconductor chip 11, the lower body 114 relatively closer to the substrate 21 may rotate more than the upper body 112. The stopper 1144 of the lower body 114 may continuously rotate with respect to the upper body 112. When the bonding surface 12 of the semiconductor chip 11 fully contacts the bonding surface 22 of the substrate 21, the stopper 1144 may contact the upper body 112 and the lower body 114 may no longer rotate with respect to the upper body 112. As the stopper 1144 contacts the upper body 112, the lower body 114 may stop rotating. At this time, an angle θ between the top surface of the stopper 1144 and the bottom surface of the upper body 112 in the groove 1122 may be about 0.5 degrees to about 12 degrees. However, the numerical value of the angle θ is just an example, and the inventive concepts are not limited thereto.

Although the attachment pad 110 in FIG. 6E is illustrated such that a sidewall of the upper body 112 is aligned with a sidewall of the lower body 114 in a straight line, like the attachment pad 110 in FIG. 6A, this is just for convenience of illustration. In reality, the upper body 112 may be inclined more than the lower body 114 such that the sidewalls of the upper body 112 and the lower body 114 may form a certain angle.

FIG. 6I is an enlarged view of a region B1 in FIG. 6A and a region B2 in FIG. 6E. In detail, FIG. 6A is a cross-sectional view of the bonding head 100 before the semiconductor chip 11 attached to the attachment pad 110 contacts the substrate 21, and FIG. 6E is a cross-sectional view of the bonding head 100 after the semiconductor chip 11 attached to the attachment pad 110 fully contacts the substrate 21.

As shown in the region B1, before the semiconductor chip 11 contacts the substrate 21, no deformation of the elastic hinge 113 may occur. As shown in the region B2, when the attachment pad 110 rotates with respect to the rotation axis AX in FIG. 6D, the elastic hinge 113 may be deformed, and thus, the rotation angle of the upper body 112 may be different from the rotation angle of the lower body 114. At this time, as the lower body 114 rotates more than the upper body 112, a width W2 of the elastic hinge 113 in the horizontal direction (the X direction and/or the Y direction) in the region B2 may be less than a width W1 of the elastic hinge 113 in the horizontal direction (the X direction and/or the Y direction) in the region B1.

When the lower body 114 rotates more than the upper body 112, the rapid rotation of the lower body 114 may be reduce or prevented using an elastic force so that slippage of the semiconductor chip 11 is reduced or prevented.

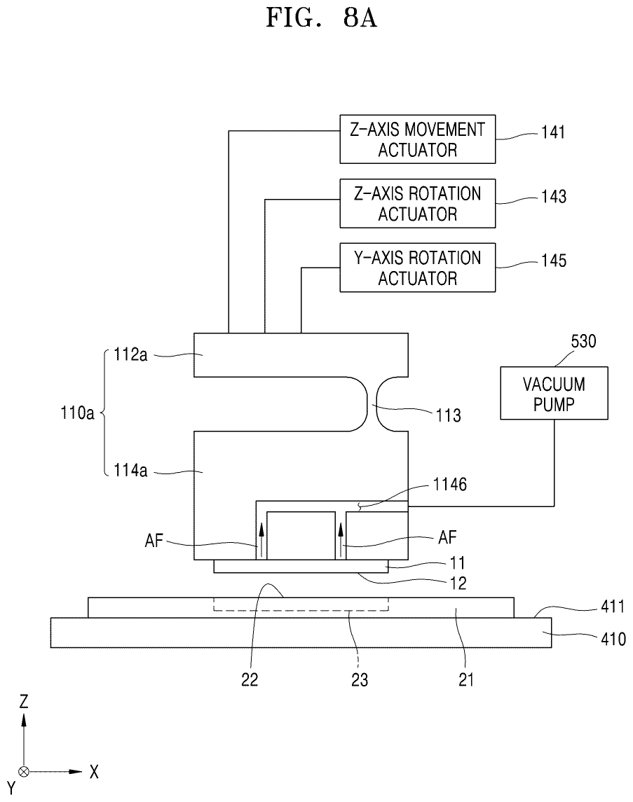

FIG. 6J is an enlarged view of a region CX in FIG. 6A. FIG. 7 is an enlarged view of a region CX1 corresponding to the region CX of the bonding head 100 of FIG. 6J, according to an example embodiment.

In the bonding head 100 of FIG. 6J, the bottom surface 1141 of the lower body 114 may have a flat shape. In this case, the semiconductor chip 11 may completely contact the bottom surface 1141 of the lower body 114, and the vacuum passage 1146 may apply vacuum pressure to the semiconductor chip 11 completely contacting the bottom surface 1141 of the lower body 114.

In a bonding head 100_a of FIG. 7, a bottom surface 1141_a of a lower body 114_a may have a convex shape. In this case, the semiconductor chip 11 may partially contact the bottom surface 1141_a of the lower body 114_a. A maximum height difference H1 in the bottom surface 1141_a of the lower body 114_a may be about 5 μm to about 30 μm. When the bottom surface 1141_a of the lower body 114_a has a convex shape and an attachment pad 110_a rotates with respect to the rotation axis AX in FIG. 6D, the semiconductor chip 11 may be more efficiently bonded to the substrate 21 without a void. When the bottom surface 1141_a of the lower body 114_a has a convex shape, the lower body 114_a may perform a rolling friction motion on the substrate 21, and accordingly, the bonding surface of the semiconductor chip 11 may be bonded to the bonding surface of the substrate 21 more smoothly in a bonding direction.

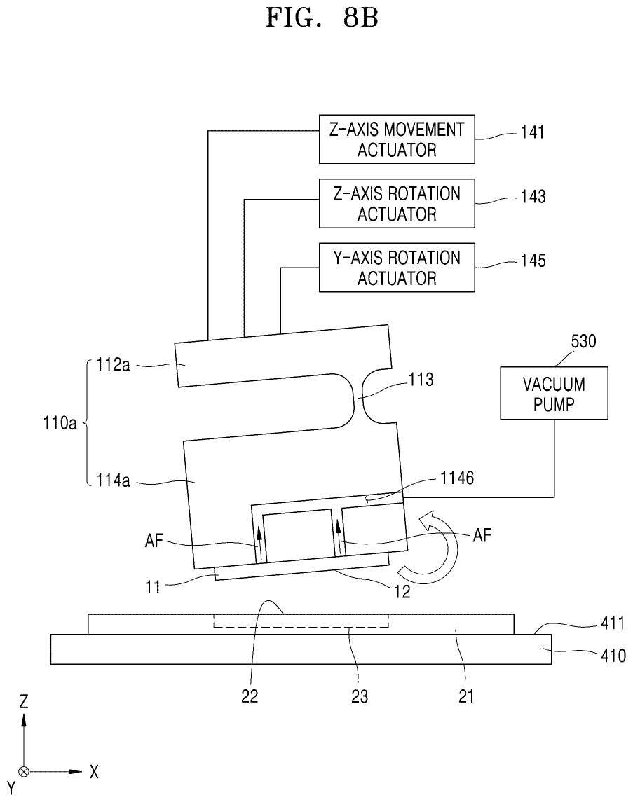

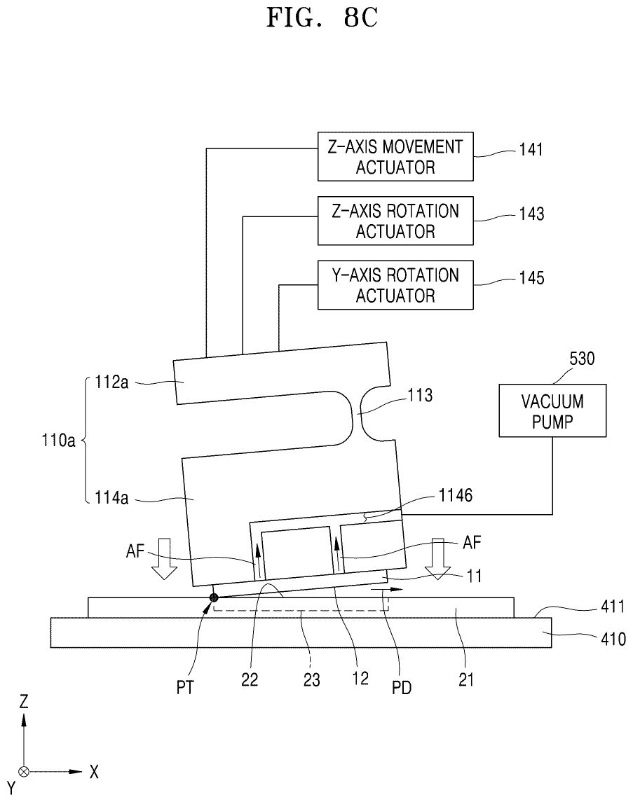

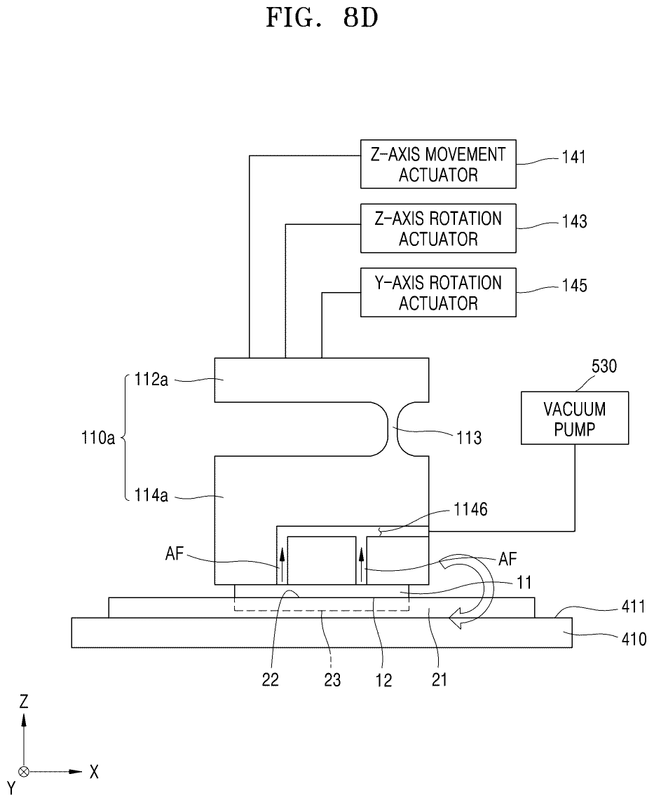

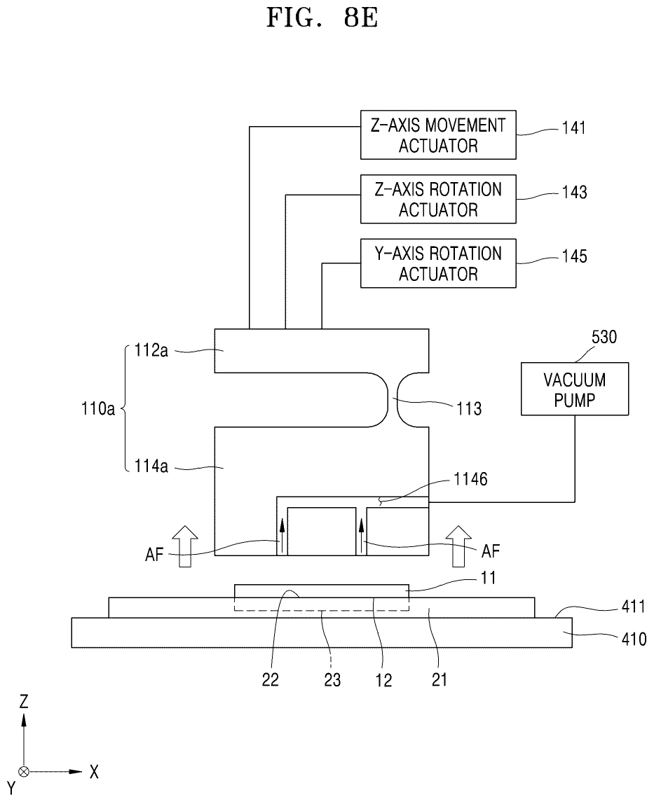

FIGS. 8A to 8E are cross-sectional views illustrating a method of controlling the bonding head 100a, according to an example embodiment.

In the descriptions of FIGS. 8A and 8E below, redundant descriptions made with respect to the FIGS. 6A to 6J are omitted below.

Referring to FIG. 8A, to stack the semiconductor chip 11 on the substrate 21, the semiconductor chip 11 may be vacuum-adsorbed and fixed to the attachment pad 110a of the bonding head 100a, which is configured to transfer the semiconductor chip 11.

Thereafter, referring to FIG. 8B, the bonding head 100a may position the attachment pad 110a such that the semiconductor chip 11 is aligned with the chip 23 of the substrate 21 in the vertical direction (the Z direction) and then rotate the attachment pad 110a by using the Y-axis rotation actuator 145. As the attachment pad 110a is rotated, the bottom surface of the semiconductor chip 11 may be inclined to the top surface of the substrate 21.

Referring to FIG. 8C, the attachment pad 110a may be lowered such that a portion of the edge of the bonding surface 12 of the semiconductor chip 11 comes into contact the bonding surface 22 of the substrate 21. In this case, a point at which the portion of the edge of the bonding surface 12 of the semiconductor chip 11 contacts the bonding surface 22 of the substrate 21 may be defined as a point PT. An axis which extends in the second horizontal direction (the Y direction) through the point PT may be defined as a rotation axis.

Referring to FIG. 8D, the attachment pad 110a may be controlled such that the bottom surface of the semiconductor chip 11 vacuum-adsorbed to the attachment pad 110a fully contacts the top surface of the substrate 21. The Z-axis movement actuator 141 may move the attachment pad 110a toward the support 410 in the vertical direction (the Z direction), and the attachment pad 110a may rotate clockwise. At this time, as described with reference to FIG. 6H, the rotation angle of the upper body 112a may be different from the rotation angle of the lower body 114a, and the lower body 114a may rotate clockwise more than the upper body 112a.

Thereafter, referring to FIG. 8E, the semiconductor chip 11 may be detached from the attachment pad 110a by releasing the vacuum-adsorption of the attachment pad 110a to the semiconductor chip 11.

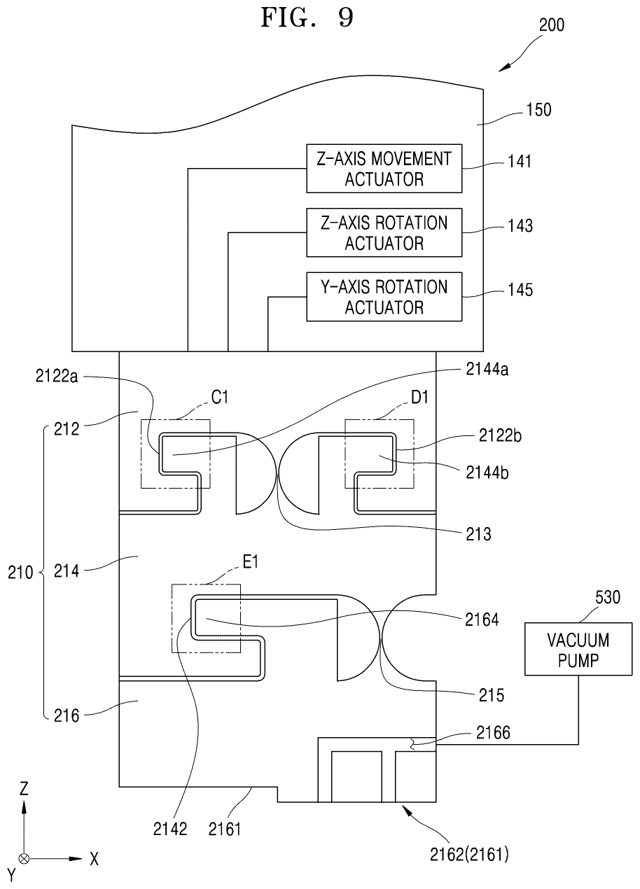

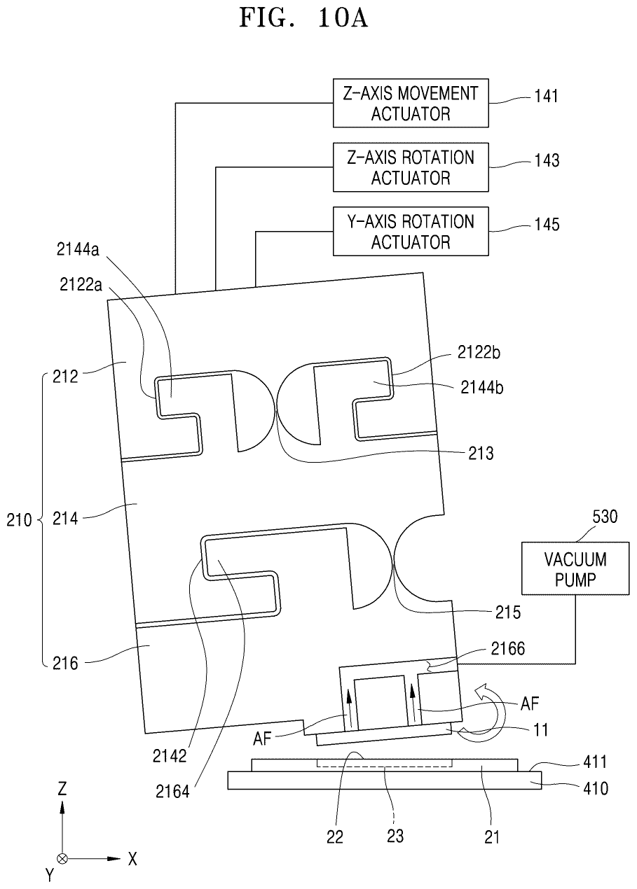

FIG. 9 is a cross-sectional view illustrating a bonding head 200 according to an example embodiment. In FIGS. 1 and 9, like reference numerals denote like elements. Therefore, redundant descriptions thereof will be brief or omitted.

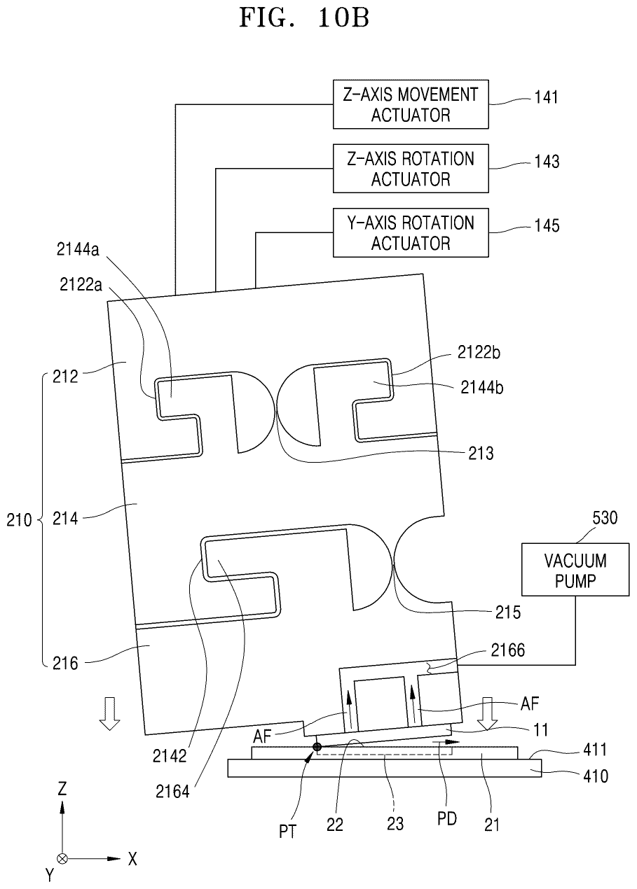

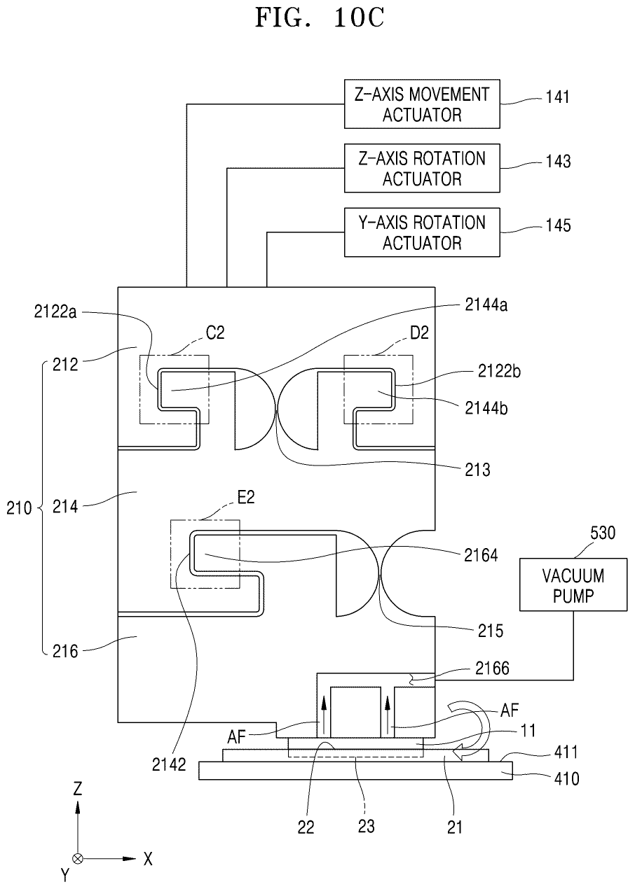

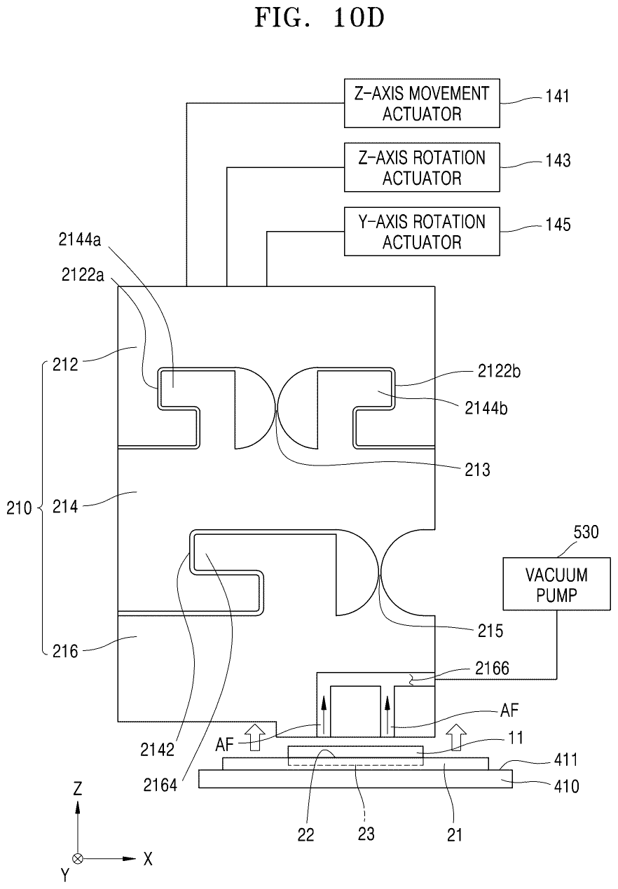

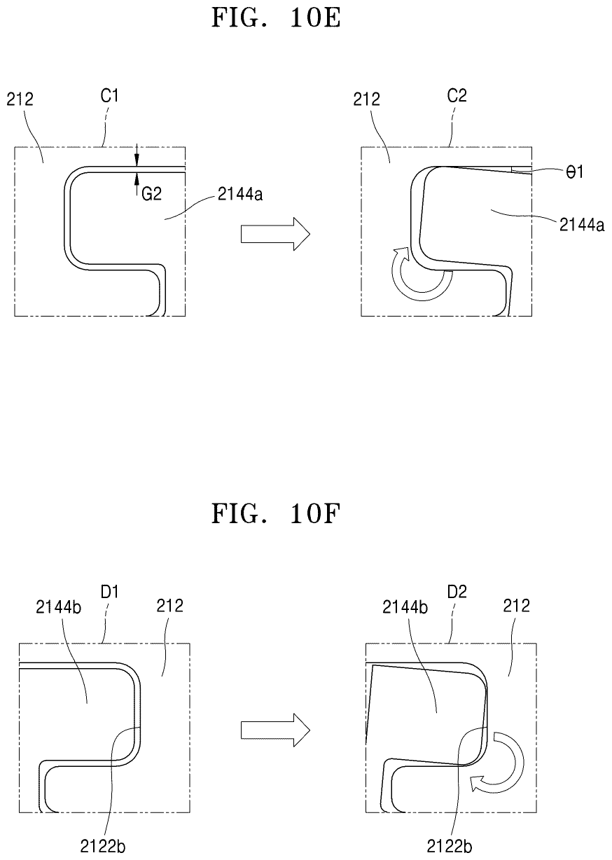

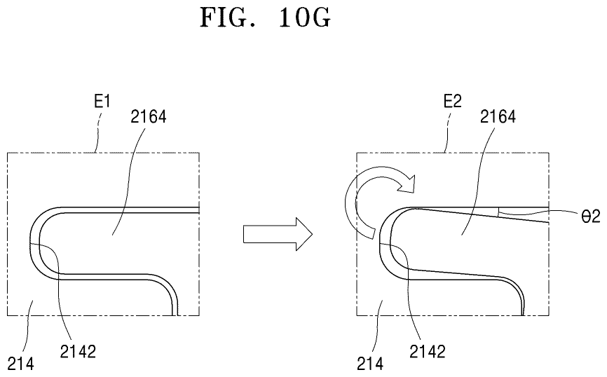

Referring to FIG. 9, the bonding head 200 may include an attachment pad 210, which includes an upper body 212, a middle body 214, and a lower body 216. The attachment pad 210 may have a pillar shape or a hexahedral shape. The lower body 216 may include a bottom surface 2161 to which the semiconductor chip 11 (see FIG. 10A) (e.g., a bonding target) is attached.

In some example embodiments, the bonding head 200 may be configured to vacuum-adsorb the semiconductor chip 11. In detail, the bonding head 200 may include a vacuum passage 2166 connected to the vacuum pump 530. The vacuum passage 2166 may be exposed by the bottom surface 2161 of the lower body 216. The vacuum passage 2166 and the vacuum pump 530 in FIG. 9 are the same as or substantially similar to the vacuum passage 1146 and the vacuum pump 530 in FIG. 1, and thus, detailed descriptions thereof are omitted.

According to an example embodiment, the upper body 212 may be on the middle body 214, and the middle body 214 may be on the lower body 216. In this case, a sidewall of the upper body 212, a sidewall of the middle body 214, and a sidewall of the lower body 114 may form a straight line.

The upper body 212 may include a first groove 2122a and a second groove 2122b separated from the first groove 2122a in the horizontal direction (the X direction and/or the Y direction). The first groove 2122a and the second groove 2122b may be formed in a lower end of the upper body 212. The middle body 214 may include a third groove 2142 in a lower end thereof. The middle body 214 may include a first stopper 2144a and a second stopper 2144b, which protrude in the horizontal direction (the X direction and/or the Y direction). The first groove 2122a and the second groove 2122b may be recessed in the horizontal direction (the X direction and/or the Y direction) in the upper body 212. The first stopper 2144a may be inserted into the first groove 2122a. The second stopper 2144b may be inserted into the second groove 2122b. As the first stopper 2144a is inserted into the first groove 2122a of the upper body 212 and the second stopper 2144b is inserted into the second groove 2122b of the upper body 212, the upper body 212 may engage with the middle body 214. As described below, the first stopper 2144a and the second stopper 2144b may not be in contact with the upper body 212. According to an example embodiment, the first stopper 2144a and the second stopper 2144b may be in mirror symmetry with respect to an axis in the vertical direction (the Z direction).

The lower body 216 may include a third stopper 2164 protruding in the horizontal direction (the X direction and/or the Y direction). The third groove 2142 may be recessed in the horizontal direction (the X direction and/or the Y direction) in the middle body 214. The third stopper 2164 may be inserted into the third groove 2142. As the third stopper 2164 is inserted into the third groove 2142 of the middle body 214, the middle body 214 may engage with the lower body 216. At this time, the third stopper 2164 may not be in contact with the middle body 214.

According to an example embodiment, the attachment pad 210 may further include a first elastic hinge 213 between the first stopper 2144a and the second stopper 2144b and a second elastic hinge 215 separated from the third stopper 2164 in the horizontal direction (the X direction and/or the Y direction). Each of the first elastic hinge 213 and the second elastic hinge 215 may have a shape of which the width decreases toward the center thereof in the vertical direction (the Z direction). The first elastic hinge 213 may connect the upper body 212 to the middle body 214. The second elastic hinge 215 may connect the middle body 214 to the lower body 216. The first elastic hinge 213 and the second elastic hinge 215 may perform similar functions to the elastic hinge 113 in FIG. 1.

According to an example embodiment, the upper body 212 and the middle body 214 may integrally form a single body through the first elastic hinge 213 and the middle body 214 and the lower body 216 may integrally form a single body through the second elastic hinge 215.

FIGS. 10A to 10G are cross-sectional views illustrating a method of controlling the bonding head 200, according to an example embodiment.

Referring to FIG. 10A, to stack the semiconductor chip 11 on the substrate 21, the method of controlling the bonding head 200 may include vacuum-adsorbing and fixing the semiconductor chip 11 to the attachment pad 210 of the bonding head 200, which is configured to transfer the semiconductor chip 11. At this time, the bonding head 200 may fix the semiconductor chip 11 to the bottom surface of the lower body 216 by using the adsorption force AF. The process of vacuum-adsorbing the semiconductor chip 11 to the lower body 216 is similar to that described with reference to FIG. 6A, and thus, detailed descriptions thereof are omitted.

Thereafter, the method of controlling the bonding head 200 may include rotating the attachment pad 210 such that the bottom surface of the semiconductor chip 11 is inclined to the top surface of the substrate 21. The bonding head 200 may move to a position where the semiconductor chip 11 is aligned with the chip 23 of the substrate 21. The substrate 21 may be located on the main surface 411 of the support 410.

The bonding head 200 may position the attachment pad 210 such that the semiconductor chip 11 is aligned with the chip 23 of the substrate 21 in the vertical direction (the Z direction) and then rotate the attachment pad 210 by using the Y-axis rotation actuator 145. The Y-axis rotation actuator 145 may rotate the attachment pad 210 such that the bonding surface 12 of the semiconductor chip 11 attached to the attachment pad 210 is inclined to the bonding surface 22 of the substrate 21. At this time, the upper body 212, the middle body 214, and the lower body 216 may integrally rotate by the same angle. This operation is similar to that described with reference to FIG. 6B, and thus, detailed descriptions thereof are omitted.

Referring to FIG. 10B, the method of controlling the bonding head 200 may include lowering the attachment pad 210 such that a portion of the edge of the semiconductor chip 11 comes into contact with the bonding surface 22 of the substrate 21. When the first edge of the bonding surface 12 of the semiconductor chip 11 comes into contact with the bonding surface 22 of the substrate 21, a point at which the first edge of the bonding surface 12 of the semiconductor chip 11 contacts the bonding surface 22 of the substrate 21 may be defined as the point PT. The description thereof is similar to that made with reference to FIGS. 6C and 6D, and thus, detailed descriptions thereof are omitted.

Referring to FIG. 10C, the method of controlling the bonding head 200 may include controlling the attachment pad 210 such that the bottom surface of the semiconductor chip 11 vacuum-adsorbed to the attachment pad 210 fully contacts the top surface of the substrate 21. The bonding head 200 may move the attachment pad 210 toward the support 410 in the vertical direction (the Z direction) by using the Z-axis movement actuator 141. At this time, the attachment pad 210 may rotate with respect to a rotation axis which extends in the second horizontal direction (the Y direction) through the point PT in FIG. 10B. The bonding between the semiconductor chip 11 and the substrate 21 may spread in the spread direction PD from the first edge of the bonding surface 12 of the semiconductor chip 11 toward the second edge of the bonding surface 12 of the semiconductor chip 11, which is opposite to the first edge. The detailed descriptions thereof are similar to those made with reference to FIGS. 6E and 6F and thus omitted below.

Referring to FIG. 10D, the method of controlling the bonding head 200 may include detaching the semiconductor chip 11 from the attachment pad 210 by releasing the vacuum-adsorption of the attachment pad 210 to the semiconductor chip 11. When the bonding between the semiconductor chip 11 and the substrate 21 is completed, the vacuum pump 530 may stop applying vacuum pressure to the vacuum passage 2166. Thereafter, the Z-axis movement actuator 141 may move the bonding head 200 upwards away from the support 410.

FIG. 10E is an enlarged view of a region C1 in FIG. 9 and a region C2 in FIG. 10C. In detail, FIG. 9 is a cross-sectional view of the bonding head 200 before the semiconductor chip 11 attached to the attachment pad 210 contacts the substrate 21, and FIG. 10C is a cross-sectional view of the bonding head 200 after the semiconductor chip 11 attached to the attachment pad 210 fully contacts the substrate 21.

As shown in the region C1, before the semiconductor chip 11 contacts the substrate 21, the first stopper 2144a inserted into the first groove 2122a may be spaced apart from the upper body 212 without contact. In this case, the distance between the first stopper 2144a inserted into the first groove 2122a and the upper body 212 may be defined as a second gap G2. According to an example embodiment, the second gap G2 may be about 10 μm to about 99 μm.

As shown in the region C2, when the attachment pad 210 rotates with respect to the point PT in FIG. 10B, the first elastic hinge 213 may be deformed, and thus, the rotation angle of the upper body 212 may be different from the rotation angle of the middle body 214. The description thereof is similar to that made with reference to FIG. 6H, and thus, detailed descriptions thereof are omitted.

The first stopper 2144a of the middle body 214 may continuously rotate with respect to the upper body 212. When the bonding surface 12 of the semiconductor chip 11 contacts an entirety of the bonding surface 22 of the substrate 21, the first stopper 2144a may contact the upper body 212 and the middle body 214 may no longer rotate with respect to the upper body 212. As the first stopper 2144a contacts the upper body 212, the middle body 214 may stop rotating. At this time, a first angle θ1 between the top surface of the first stopper 2144a and the bottom surface of the upper body 212 in the first groove 2122a may be about 0.5 degrees to about 12 degrees. However, the numerical value of the first angle θ1 is just an example, and the inventive concepts are not limited thereto.

FIG. 10F is an enlarged view of a region D1 in FIG. 9 and a region D2 in FIG. 10C. Redundant descriptions made with respect to FIG. 10E are omitted below.

As shown in the region D1, before the semiconductor chip 11 contacts the substrate 21, the second stopper 2144b inserted into the second groove 2122b may be spaced apart from the upper body 212 without contact.

As shown in the region D2, when the attachment pad 210 rotates with respect to the point PT in FIG. 10B, the first elastic hinge 213 may be deformed, and thus, the rotation angle of the upper body 212 may be different from the rotation angle of the middle body 214. The description thereof is similar to that made with reference to FIG. 6H, and thus, detailed descriptions thereof are omitted.

Referring to FIGS. 10E and 10F, when the attachment pad 210 rotates, the bottom surface of the second stopper 2144b comes into contact with the upper body 212 in the second groove 2122b while the top surface of the first stopper 2144a comes into contact with the upper body 212 in the first groove 2122a.

FIG. 10G is an enlarged view of a region E1 in FIG. 9 and a region E2 in FIG. 10C. Redundant descriptions made with respect to FIG. 10E are omitted below.

As shown in the region E1, before the semiconductor chip 11 contacts the substrate 21, the third stopper 2164 inserted into the third groove 2142 may be spaced apart from the middle body 214 without contact. As shown in the region E2, when the attachment pad 210 rotates with respect to the point PT in FIG. 10B, the second elastic hinge 215 may be deformed, and thus, the rotation angle of the middle body 214 may be different from the rotation angle of the lower body 216. The description thereof is similar to that made with reference to FIG. 6H, and thus, detailed descriptions thereof are omitted. However, because the lower body 216 including the third stopper 2164 is closer to the substrate 21 and the point PT, through which the rotation axis passes, than the middle body 214 including the first stopper 2144a, the lower body 216 rotates more than the middle body 214. Because the middle body 214 is closer to the substrate 21 and the point PT, through which the rotation axis passes, than the upper body 212, the middle body 214 rotates more than the upper body 212. Accordingly, a second angle θ2 2 between the top surface of the third stopper 2164 and the top surface of the middle body 214 in the third groove 2142 may be greater than the first angle θ1 in FIG. 10E.

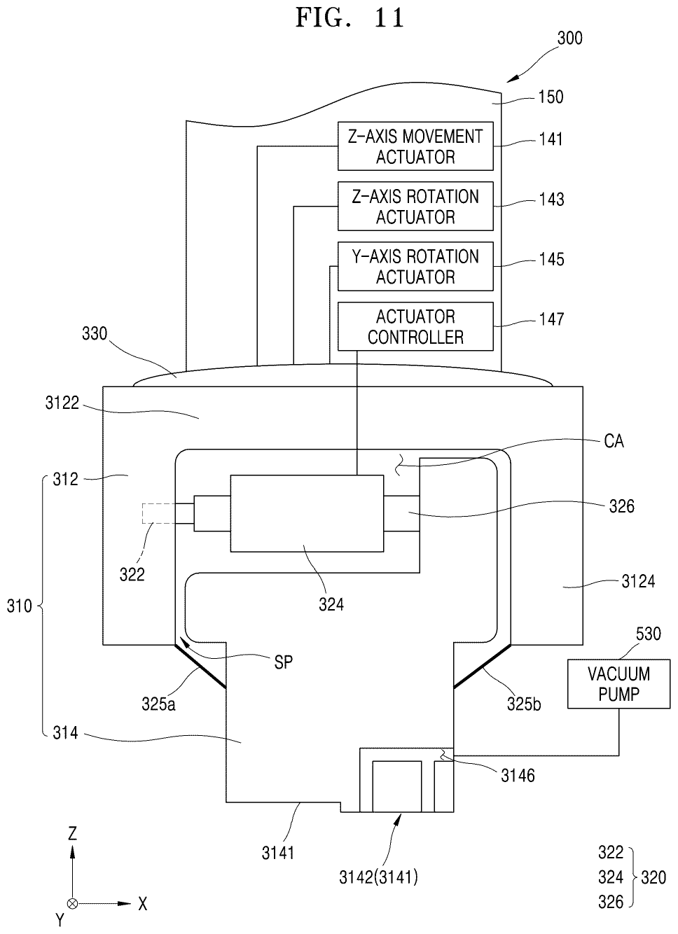

FIG. 11 is a cross-sectional view illustrating a bonding head 300 according to an example embodiment.

The bonding head 300 may include an attachment pad 310, which includes an upper body 312 and a lower body 314. In the bonding head 300 of FIG. 11, unlike the bonding head 100 of FIG. 1 and the bonding head 200 of FIG. 9, the upper body 312 and the lower body 314 may not be integrally formed and may be separated from each other. The upper body 312 may provide an inner space SP in which the lower body 314 may be inserted. The upper body 312 may include an outer portion 3124 defining the inner space SP, and the lower body 314 may be inserted into the outer portion 3124 of the upper body 312.

The lower body 314 may include a bottom surface 3141, to which the semiconductor chip 11 corresponding to a bonding target is attached. The lower body 314 may include a step portion 3142, which is at a lower portion of the lower body 314 and to which the semiconductor chip 11 is attached. The bottom surface 3141 of the step portion 3142 of the lower body 314 may be at a lower level than the bottom surface 3141 of the other portion of the lower body 314 in the vertical direction (the Z direction). A region at one side of the center of the lower body 314 may be defined as the step portion 3142, but example embodiments are not limited thereto. According to an example embodiment, in a plan view of the lower body 314, the area of the step portion 3142 may be greater than the area of the other portion of the lower body 314. Conversely, according to an example embodiment, in a plan view of the lower body 314, the area of the step portion 3142 may be less than the area of the other portion of the lower body 314.

In some example embodiments, the bonding head 300 may configured to vacuum-adsorb the semiconductor chip 11. The bonding head 300 may include a vacuum passage 3146 connected to the vacuum pump 530. The vacuum passage 3146 may be exposed by the bottom surface 3141 of the step portion 3142 of the lower body 314. The descriptions of the vacuum passage 3146 and the vacuum pump 530 are similar to the vacuum passage 1146 and the vacuum pump 530 described with reference to FIG. 1, and thus, detailed descriptions thereof are omitted.

According to an example embodiment, the attachment pad 310 may include an elastic connector (e.g., 325a and 325b) configured to connect the outer portion 3124 of the upper body 312 to the lower body 314. The elastic connector (325a and 325b) may extend in a diagonal direction to the vertical direction (the Z direction). As described in detail below, when the lower body 314 rotates about an axis in the second horizontal direction (the Y direction) with respect to the upper body 312 that is stationary, the elastic connector (325a and 325b) may reduce or prevent the lower body 314 from rapidly rotating, thereby reducing or preventing slippage of the semiconductor chip 11.

The elastic connector may include a first elastic connector 325a and a second elastic connector 325b, which is located opposite the first elastic connector 325a with respect to the lower body 314 that is between the first elastic connector 325a and the second elastic connector 325b. For example, when the lower body 314 rotates about the axis in the second horizontal direction (the Y direction) with respect to the upper body 312 that is stationary, the first elastic connector 325a may be separated from the second elastic connector 325b by the lower body 314 in the first horizontal direction (the X direction). In this case, the first elastic connector 325a and the second elastic connector 325b may be in mirror symmetry with respect to an axis in the vertical direction (the Z direction). The first elastic connector 325a and the second elastic connector 325b may include an elastic material such as rubber.

According to an example embodiment, space between the upper body 312 and the lower body 314 in the inner space SP of the upper body 312 may be defined as a cavity CA. In this case, the bonding head 300 may include a parallel movement actuator 320 in the cavity CA. The parallel movement actuator 320 may include a main body 324, a first connector 322, and a second connector 326. The first connector 322 and the second connector 326 may have a cylindrical shape or a quadrangular pillar shape. An end of the first connector 322 may be connected to the outer portion 3124 of the upper body 312 and an opposite end of the first connector 322 may be connected to the main body 324 of the parallel movement actuator 320. An end of the second connector 326 may be connected to the lower body 314 and an opposite end of the second connector 326 may be connected to the main body 324 of the parallel movement actuator 320. For example, the parallel movement actuator 320 may include a linear motor or a piezoelectric actuator of which the length may vary with an electrical signal.

According to an example embodiment, the bonding head 300 may include an actuator controller 147 configured to control the parallel movement actuator 320. The actuator controller 147 may include a receiver and a transmitter to receive and transmit electrical signals from and to the parallel movement actuator 320. The actuator controller 147 may be implemented by hardware, firmware, software, or a combination thereof.

In an example embodiment, the bonding head 300 may include the Z-axis movement actuator 141 for the up-and-down movement of the attachment pad 310. The Z-axis movement actuator 141 in FIG. 11 is substantially the same as the Z-axis movement actuator 141 in FIG. 1, and thus, detailed descriptions thereof are omitted.

According to an example embodiment, the bonding head 300 may include a rotary part 330 on the upper body 312 and the Y-axis rotation actuator 145. The Y-axis rotation actuator 145 may rotate the rotary part 330, which is on the upper body 312, around the second horizontal direction (the Y direction). According to an example embodiment, the rotary part 330 may include a gyro sensor and may be configured to sense a rotation value based on the Y axis. The rotary part 330 may operate in a rotary mode or a fixed mode. In the rotary mode, the rotary part 330 may be freely rotated around the second horizontal direction (the Y direction) by the Y-axis rotation actuator 145. In the fixed mode, the rotary part 330 may not be rotated by the Y-axis rotation actuator 145 and may be maintained in a tilting angle.

In an example embodiment, the bonding head 300 may include the Z-axis rotation actuator 143. The Z-axis rotation actuator 143 is the same as or substantially similar to the Z-axis rotation actuator 143 in FIG. 1, and thus, detailed descriptions thereof are omitted.

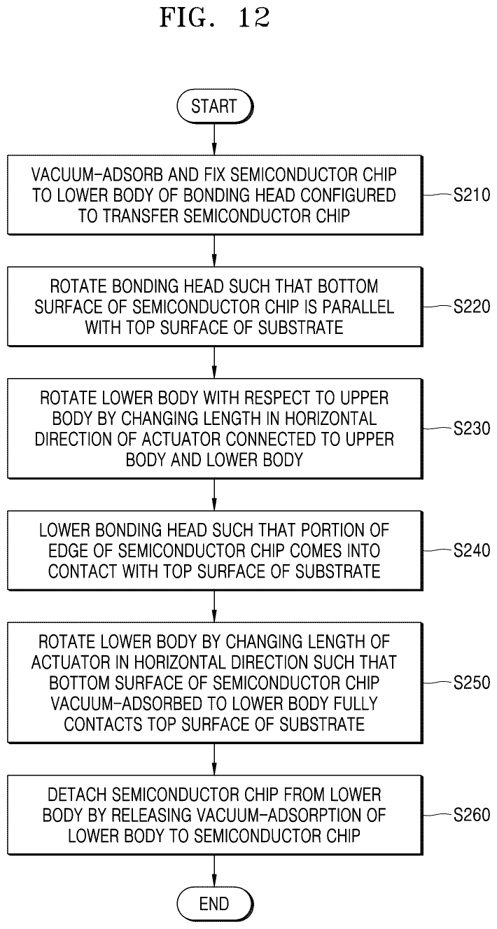

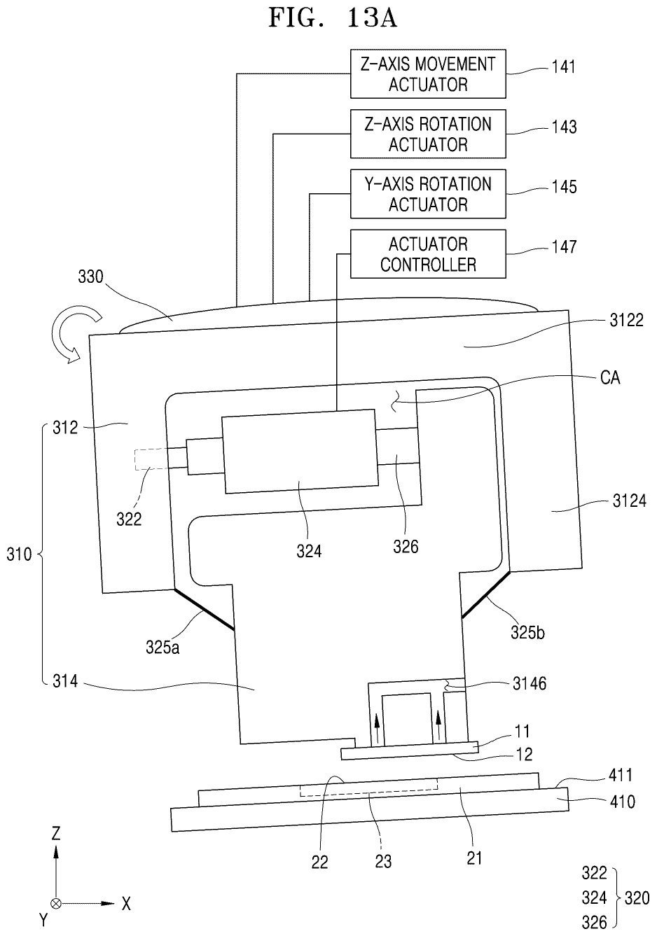

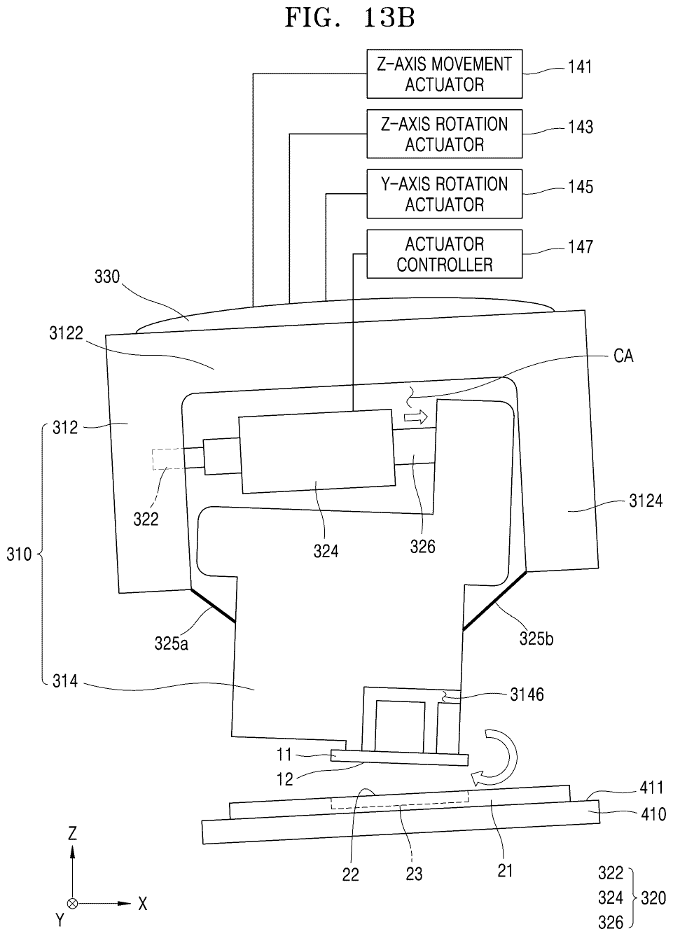

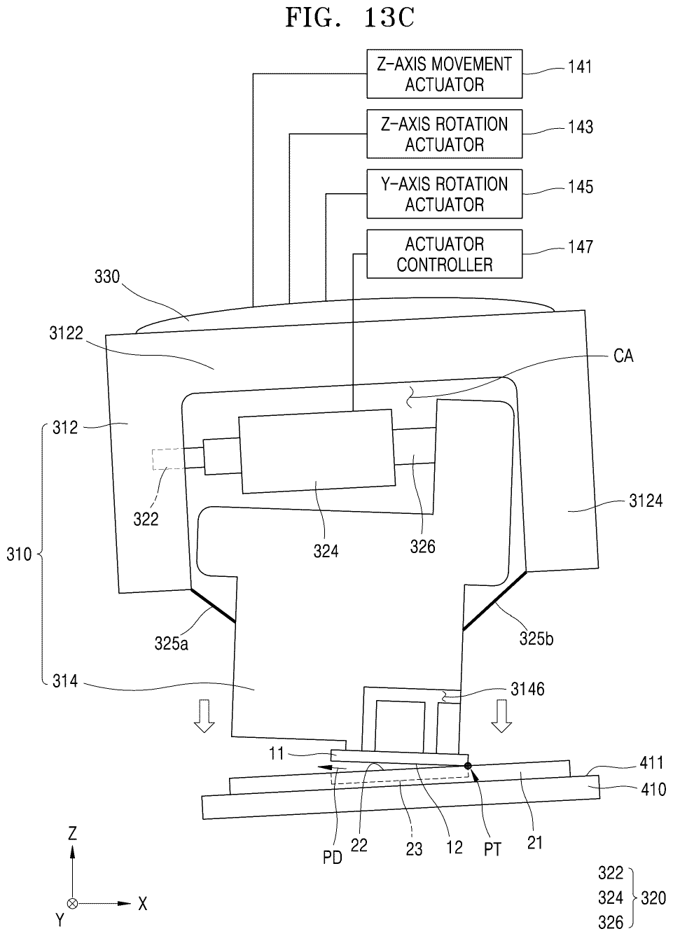

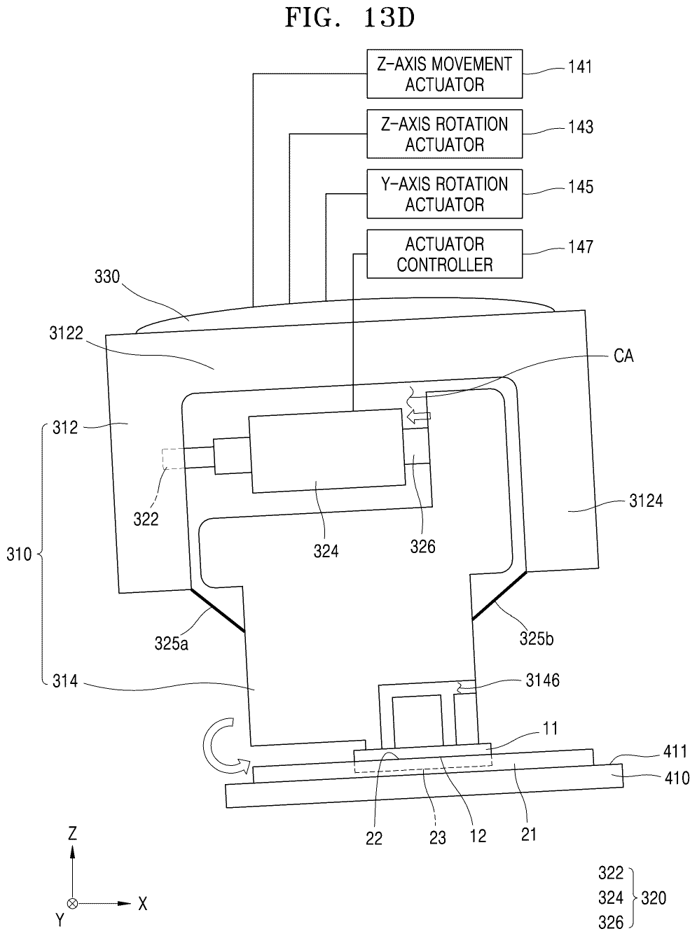

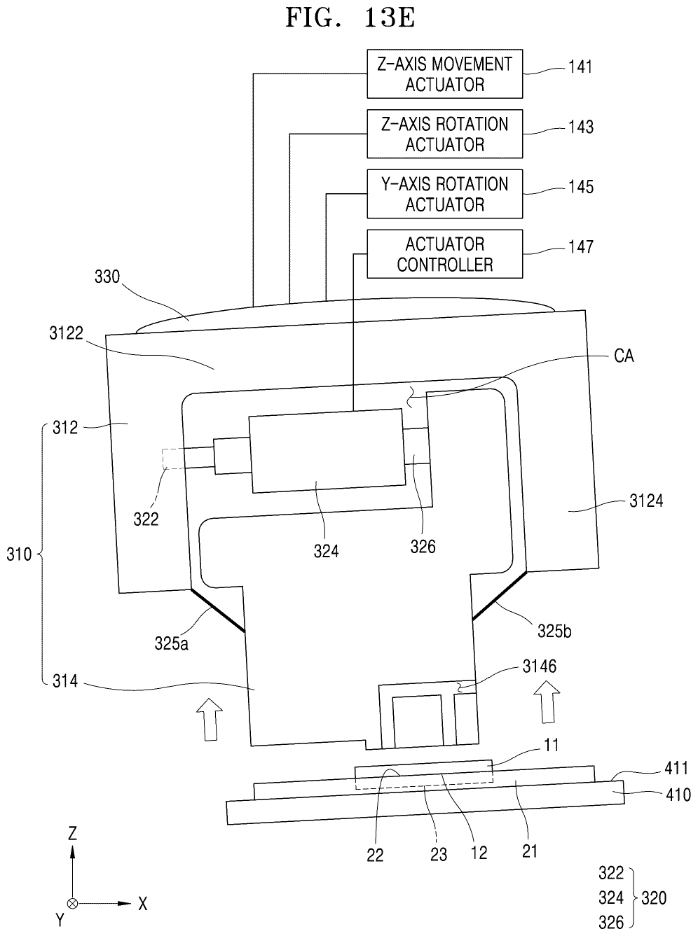

FIG. 12 is a flowchart of a method of controlling the bonding head 300, according to an example embodiment. FIGS. 13A to 13E are cross-sectional views illustrating a method of controlling the bonding head 300, according to an example embodiment. Redundant descriptions made with respect to the FIGS. 6A to 6J are brief or omitted below.

Referring to FIGS. 12 and 13A, to stack the semiconductor chip 11 on the substrate 21, the method of controlling the bonding head 300 may include vacuum-adsorbing and fixing the semiconductor chip 11 to the lower body 314 of the bonding head 300, which is configured to transfer the semiconductor chip 11, in operation S210.

According to an example embodiment, the bonding head 300 may fix the semiconductor chip 11 to the bottom surface 3141 of the step portion 3142 of the lower body 314. The descriptions of a method by which the bonding head 300 fixes the semiconductor chip 11 by using the adsorption force AF through the vacuum passage 3146 are the same as or substantially similar to that described above with reference to FIGS. 5 and 6A and thus omitted.

According to an example embodiment, the method of controlling the bonding head 300 may include rotating the bonding head 300 such that the bonding surface 12 of the semiconductor chip 11 is parallel with the bonding surface 22 of the substrate 21 in operation S220.

According to an example embodiment, the support 410, on which the substrate 21 is mounted, may tilt. In this case, the bonding head 300 may rotate the rotary part 330 by using the Y-axis rotation actuator 145. The attachment pad 310 integrally rotating with the rotary part 330 may also be rotated by the Y-axis rotation actuator 145. The Y-axis rotation actuator 145 may rotate the attachment pad 310 by using the second horizontal direction (the Y direction), which is parallel with the main surface 411 of the support 410 on which the substrate 21 is mounted, as a rotation axis. After the rotation of the attachment pad 310, the rotary part 330 may be changed into the fixed mode and may store a tilting angle at the end of the rotation and maintain the tilting angle. When the Y-axis rotation actuator 145 rotates the bonding head 300, the upper body 312 and the lower body 314 may integrally rotate by the same angle. The detailed descriptions of the operation of rotating the bonding head 300 by using the Y-axis rotation actuator 145 are the same as or substantially similar to that described above with reference to FIGS. 5 and 6B, and thus omitted.

Referring to FIGS. 12 and 13B, the method of controlling the bonding head 300 may include rotating the lower body 314 with respect to the upper body 312 by changing the length of the parallel movement actuator 320, which is connected to the upper body 312 and the lower body 314, in the horizontal direction (the X direction and/or the Y direction) in operation S230. As shown in FIG. 13B, the second connector 326 of the parallel movement actuator 320 fixed to the lower body 314 may be lengthened in the first horizontal direction (the X direction). The actuator controller 147 may transmit an electrical signal to the parallel movement actuator 320 to lengthen the second connector 326. When the second connector 326 connected to an upper end portion of the lower body 314 is lengthened, the lower body 314 may rotate around the second horizontal direction (the Y direction). At this time, the length of the first elastic connector 325a connected to the lower body 314 may be reduced, and the length of the second elastic connector 325b connected to the lower body 314 may be increased. The upper body 312 may be fixed without rotating while the lower body 314 rotates.

Referring to FIGS. 12 and 13C, the method of controlling the bonding head 300 may include lowering the bonding head 300 such that a portion of the edge of the semiconductor chip 11 comes into contact with the top surface of the substrate 21 in operation S240. When the first edge of the bonding surface 12 of the semiconductor chip 11 comes into contact with the bonding surface 22 of the substrate 21, a point where the first edge of the bonding surface 12 of the semiconductor chip 11 contacts the bonding surface 22 of the substrate 21 may be defined as the point PT. Descriptions thereof are similar to those made with reference to FIGS. 6C and 6D and thus omitted.

Referring to FIGS. 12 and 13D, the method of controlling the bonding head 300 may include rotating the lower body 314 by changing the length of the parallel movement actuator 320 in the horizontal direction (the X direction and/or the Y direction) such that the bottom surface of the semiconductor chip 11 vacuum-adsorbed to the lower body 314 contacts an entirety of the top surface of the substrate 21 in operation S250.

As shown in FIG. 13D, the length in the first horizontal direction (the X direction) of the second connector 326 of the parallel movement actuator 320 fixed to the lower body 314 may be reduced. The actuator controller 147 may transmit an electrical signal to the parallel movement actuator 320 to reduce the length of the second connector 326. As the length of the second connector 326 connected to the upper end portion of the lower body 314 is reduced, the lower body 314 may rotate anticlockwise (e.g., counterclockwise) around the second horizontal direction (the Y direction). At this time, the length of the first elastic connector 325a connected to the lower body 314 may be increased, and the length of the second elastic connector 325b may be reduced. The upper body 312 may be fixed without rotating while the lower body 314 rotates.

The bonding between the semiconductor chip 11 and the substrate 21 may spread in the spread direction PD from the first edge of the bonding surface 12 of the semiconductor chip 11 toward the second edge of the bonding surface 12 of the semiconductor chip 11, which is opposite to the first edge. The detailed descriptions thereof are similar to those made with reference to FIGS. 6E and 6F and thus omitted below.

Referring to FIGS. 12 and 13E, the method of controlling the bonding head 300 may include detaching the semiconductor chip 11 from the attachment pad 310 by releasing the vacuum-adsorption of the attachment pad 310 to the semiconductor chip 11 in operation S260. When the bonding between the semiconductor chip 11 and the substrate 21 is completed, the vacuum pump 530 may stop applying vacuum pressure to the vacuum passage 3146. Thereafter, the Z-axis movement actuator 141 may move the bonding head 300 upwards away from the support 410.

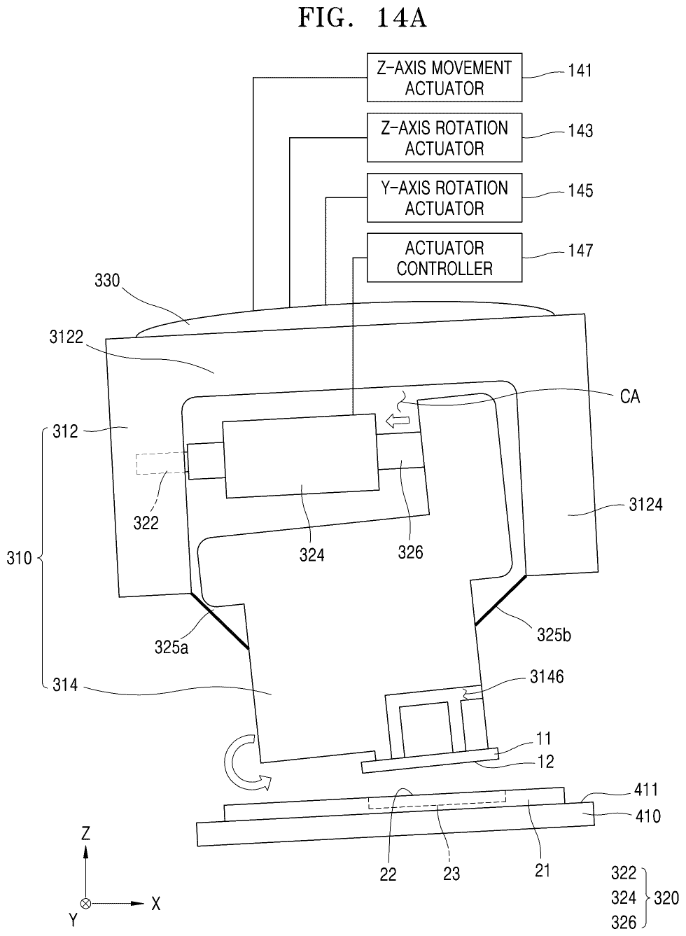

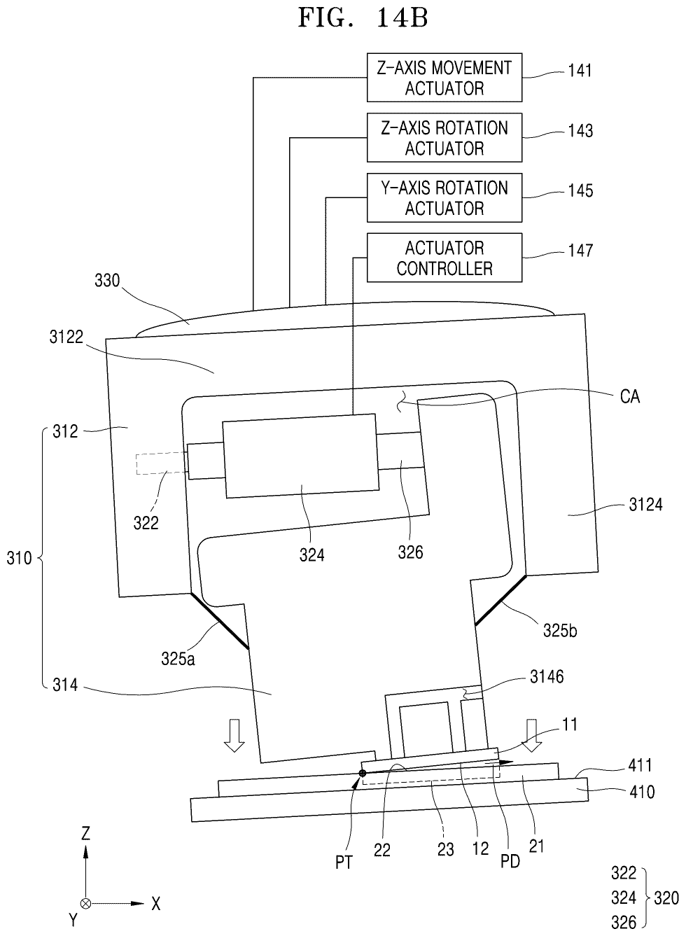

FIGS. 14A to 14C are cross-sectional views illustrating a method of controlling the bonding head 300, according to an example embodiment. The method of controlling the bonding head 300 illustrated in FIGS. 14A to 14C is the same as or substantially similar to that illustrated in FIGS. 13A to 13E, except for a rotation direction. Therefore, redundant descriptions made with respect to the FIGS. 13A to 13E are brief or omitted below.

Referring to FIG. 14A, the method of controlling the bonding head 300 may include rotating the lower body 314 with respect to the upper body 312 by changing the length of the parallel movement actuator 320, which is connected to the upper body 312 and the lower body 314, in the horizontal direction (the X direction and/or the Y direction). As shown in FIG. 14A, the second connector 326 of the parallel movement actuator 320 fixed to the lower body 314 may be shortened in the first horizontal direction (the X direction). The actuator controller 147 may transmit an electrical signal to the parallel movement actuator 320 to shorten the second connector 326. When the second connector 326 connected to an upper end portion of the lower body 314 is shortened, the lower body 314 may rotate anticlockwise (e.g., counterclockwise) around the second horizontal direction (the Y direction). At this time, the length of the first elastic connector 325a connected to the lower body 314 may be increased, and the length of the second elastic connector 325b connected to the lower body 314 may be decreased. The upper body 312 may be fixed without rotating while the lower body 314 rotates.

Referring to FIG. 14B, the method of controlling the bonding head 300 may include lowering the bonding head 300 such that a portion of the edge of the semiconductor chip 11 comes into contact with the top surface of the substrate 21 When the first edge of the bonding surface 12 of the semiconductor chip 11 comes into contact with the bonding surface 22 of the substrate 21, a point where the first edge of the bonding surface 12 of the semiconductor chip 11 contacts the bonding surface 22 of the substrate 21 may be defined as the point PT. Descriptions thereof are similar to those made with reference to FIG. 6C and thus omitted.

Referring to FIG. 14C, the method of controlling the bonding head 300 may include rotating the lower body 314 by changing the length of the parallel movement actuator 320 in the horizontal direction (the X direction and/or the Y direction) such that the bottom surface of the semiconductor chip 11 vacuum-adsorbed to the lower body 314 contacts an entirety of the top surface of the substrate 21.

As shown in FIG. 14C, the length in the first horizontal direction (the X direction) of the second connector 326 of the parallel movement actuator 320 fixed to the lower body 314 may be increased. The actuator controller 147 may transmit an electrical signal to the parallel movement actuator 320 to increase the length of the second connector 326. As the length of the second connector 326 connected to the upper end portion of the lower body 314 is increased, the lower body 314 may rotate clockwise around the second horizontal direction (the Y direction). At this time, the length of the first elastic connector 325a connected to the lower body 314 may be reduced, and the length of the second elastic connector 325b may be increased. The upper body 312 may be fixed without rotating while the lower body 314 rotates.

The bonding between the semiconductor chip 11 and the substrate 21 may spread in the spread direction PD from the first edge of the bonding surface 12 of the semiconductor chip 11 toward the second edge of the bonding surface 12 of the semiconductor chip 11, which is opposite to the first edge. The detailed descriptions thereof are similar to those made with reference to FIGS. 6E and 6F and thus omitted below.

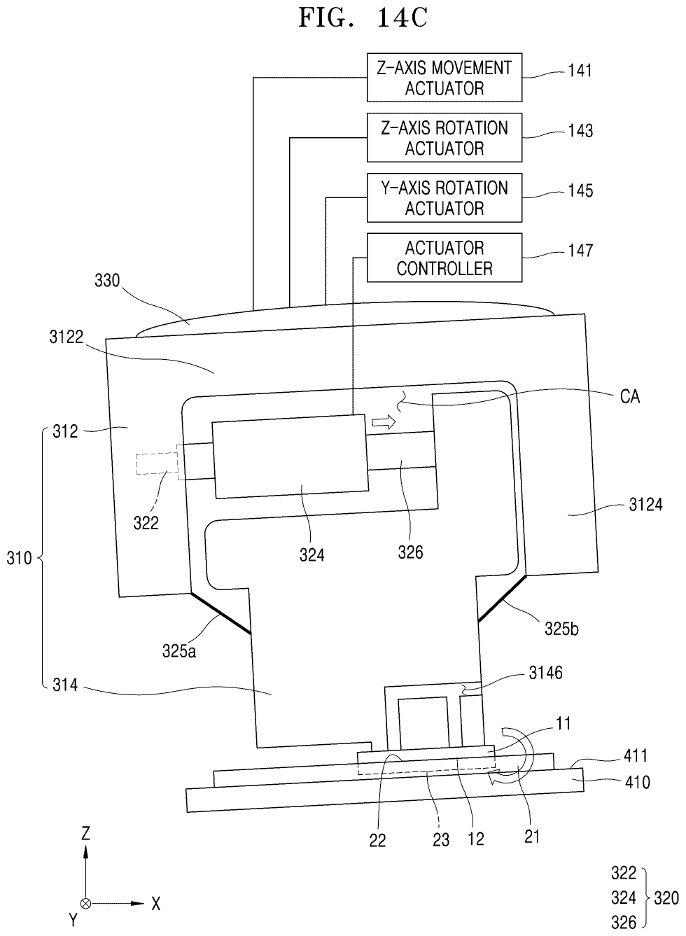

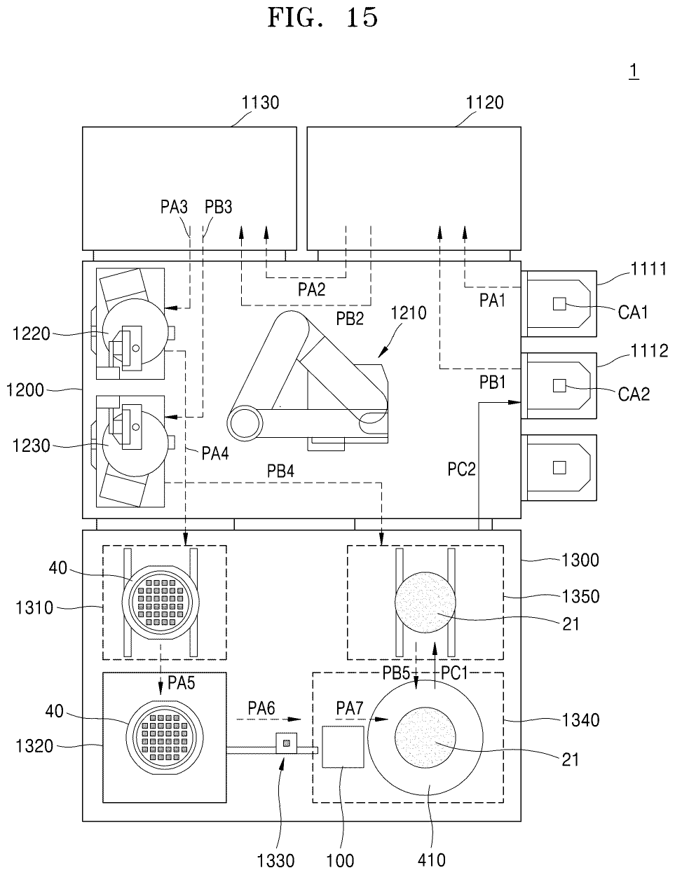

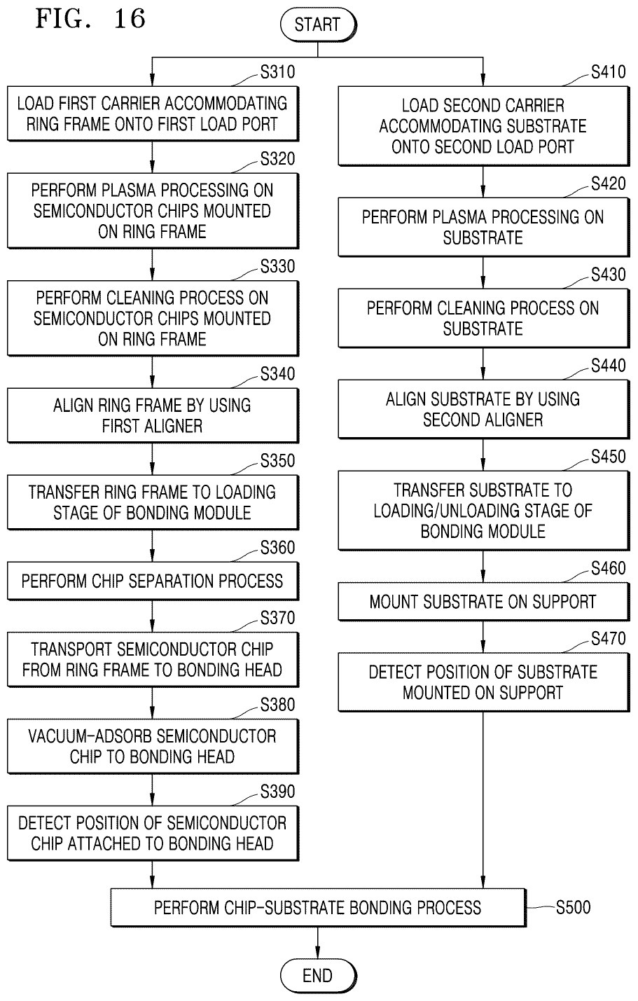

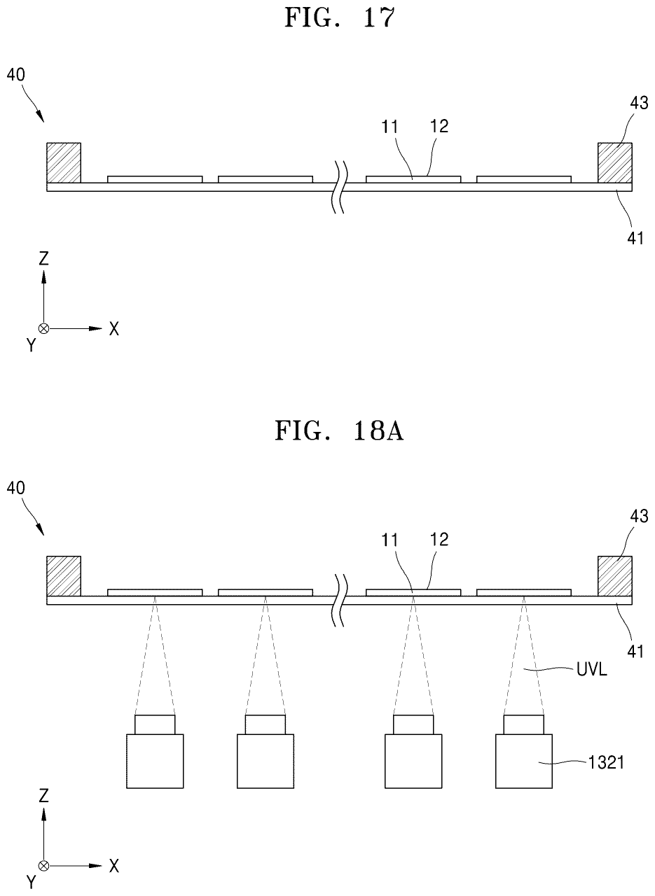

FIG. 15 is a schematic diagram of the configuration of a semiconductor manufacturing apparatus 1 according to an example embodiment. FIG. 16 is a flowchart of a semiconductor manufacturing method using the semiconductor manufacturing apparatus 1 of FIG. 15. FIG. 17 is a cross-sectional view of a ring frame 40 on which semiconductor chips 11 are mounted.

Referring to FIGS. 15 to 17, a first carrier CA1 accommodating the ring frame 40, on which the semiconductor chips 11 are mounted, may be loaded onto a first load port 1111 in operation S310.

For example, the first carrier CA1 may include a front opening unified pod (FOUP). The ring frame 40 may include an adhesive film 41, to which the semiconductor chips 11 are attached, and a frame body 43, which has a ring shape coupled to the edge of the adhesive film 41.

The ring frame 40 may be transferred from the first carrier CA1 to a plasma processing module 1120 and the plasma processing module 1120 may perform plasma processing on the semiconductor chips 11 mounted on the ring frame 40, in operation S320.

In operation S320, the ring frame 40 may be transferred by a transfer robot 1210 included in an equipment front end module (EFEM) 1200. For example, the transfer robot 1210 may carry out the ring frame 40 from the first carrier CA1 and transfer the ring frame 40 to the plasma processing module 1120 along a first chip transfer path PA1 in FIG. 15.

In operation S320, the plasma processing module 1120 may include a chamber providing a plasma processing space and a plasma generator generating plasma. The plasma processing module 1120 may perform plasma processing on the bonding surface 12 of each of the semiconductor chips 11 such that the bonding surface 12 of each semiconductor chip 11 has a bonding force suitable for a bonding process.

When the plasma processing is completely performed on the semiconductor chips 11, the ring frame 40 may be transferred to a cleaning module 1130 and the cleaning module 1130 may perform a cleaning process on the semiconductor chips 11 mounted on the ring frame 40, in operation S330.

In operation S330, the ring frame 40 may be transferred by the transfer robot 1210 of the EFEM 1200. For example, the transfer robot 1210 may transfer the ring frame 40 from the plasma processing module 1120 to the cleaning module 1130 along a second chip transfer path PA2 in FIG. 15.

In operation S330, the cleaning module 1130 may be configured to perform wet cleaning on the semiconductor chips 11. The cleaning module 1130 may include a chamber providing a cleaning space and a cleaning solution injection nozzle providing a cleaning solution used for wet cleaning. The cleaning module 1130 may inject a cleaning solution, which includes deionized water, to the semiconductor chips 11 to clean contaminants off the surface of the semiconductor chips 11.

When the cleaning process is completely performed on the semiconductor chips 11, the ring frame 40 may be transferred to a first aligner 1220 included in the EFEM 1200 and the first aligner 1220 may align the ring frame 40 with a desired (or alternatively, preset) direction, in operation S340. In operation S340, the transfer robot 1210 may transfer the ring frame 40 from the cleaning module 1130 to the first aligner 1220 along a third chip transfer path PA3 in FIG. 15.

Thereafter, the ring frame 40 may be transferred from the first aligner 1220 to a loading stage 1310 of a bonding module 1300 in operation S350. In operation S350, the transfer robot 1210 may transfer the ring frame 40 from the first aligner 1220 to the loading stage 1310 of the bonding module 1300 along a fourth chip transfer path PA4 in FIG. 15. The loading stage 1310 may include a transport member transporting the ring frame 40.

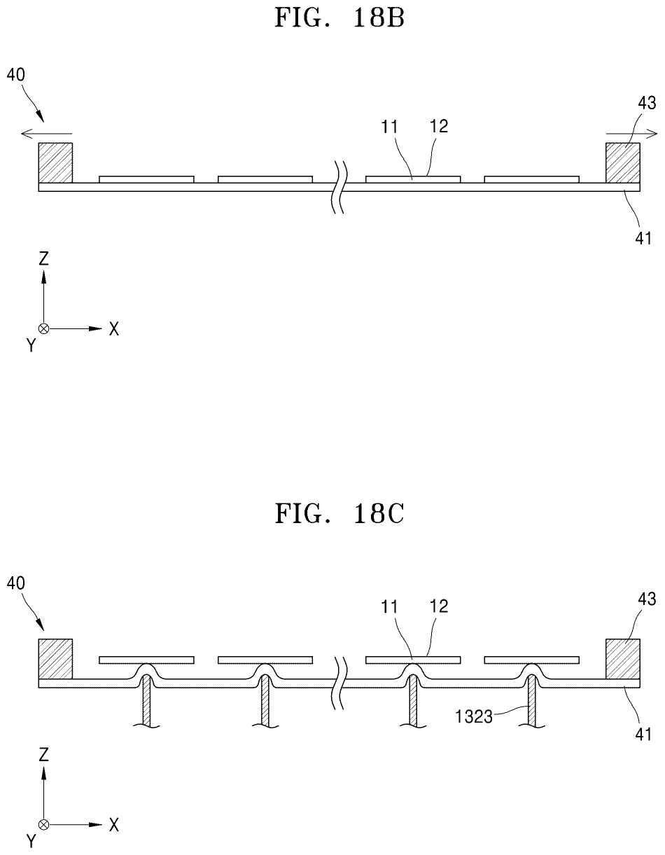

FIGS. 18A to 18C are conceptual diagrams illustrating a chip separation process performed by a chip separation stage 1320 of the bonding module 1300, according to an example embodiment.

Referring to FIGS. 15, 16, 18A, 18B, and 18C, the ring frame 40 may be transported from the loading stage 1310 to the chip separation stage 1320 along a fifth chip transfer path PA5 in FIG. 15 and the chip separation stage 1320 may perform a chip separation process to separate the semiconductor chips 11 from the ring frame 40, in operation S360.

In operation S360, the chip separation process may include various processes of reducing the adhesive strength of the adhesive film 41 of the ring frame 40 so that the semiconductor chips 11 may be readily separated from the adhesive film 41. In some example embodiments, the chip separation process performed by the chip separation stage 1320 may include an ultraviolet (UV) radiation process, a film expanding process, and a chip ejecting process.

FIG. 18A illustrates the UV radiation process performed by the chip separation stage 1320. The chip separation stage 1320 may include a UV light source 1321 configured to radiate UV light UVL to the adhesive film 41 of the ring frame 40. The UV light source 1321 may locally reduce the adhesion of the adhesive film 41 by radiating the UV light UVL to portions of the adhesive film 41, to which the semiconductor chips 11 are respectively attached.

FIG. 18B illustrates the film expanding process performed by the chip separation stage 1320. The chip separation stage 1320 may include an expanding tool configured to pull the frame body 43 outward in the radial direction so that the adhesive film 41 is stretched. By expanding the adhesive film 41, the expanding tool may increase the distance between the semiconductor chips 11 to a level desired or required for a subsequent process of picking up each of the semiconductor chips 11.

FIG. 18C illustrates the chip ejecting process performed by the chip separation stage 1320. The chip separation stage 1320 may include an ejector 1323 configured to physically pressing the adhesive film 41. The ejector 1323 may include a pin or rod-shaped member connected to a driving member such as an actuator. The ejector 1323 may push each of the semiconductor chips 11 upward by pressing the bottom surface of the adhesive film 41, which is opposite to the top surface of the adhesive film 41, wherein each semiconductor chip 11 is attached to the top surface of the adhesive film 41. For example, the ejector 1323 may lift the semiconductor chip 11 while moving upward from below the center of the semiconductor chip 11. When the semiconductor chip 11 pressurized by the ejector 1323 is lifted, the adhesive area between the semiconductor chip 11 and the adhesive film 41 may be reduced, thereby decreasing the adhesive strength between the semiconductor chip 11 and the adhesive film 41.

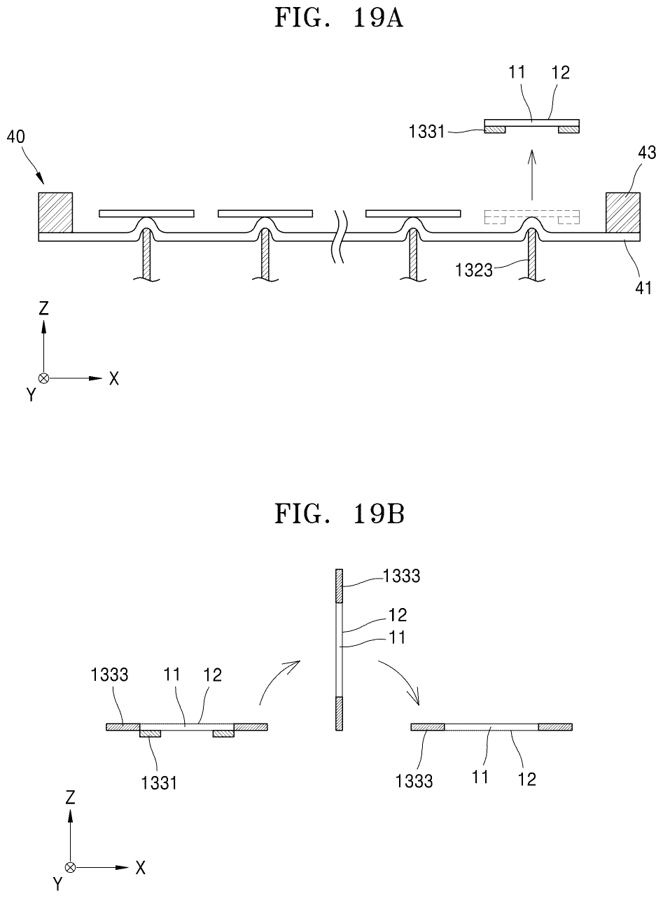

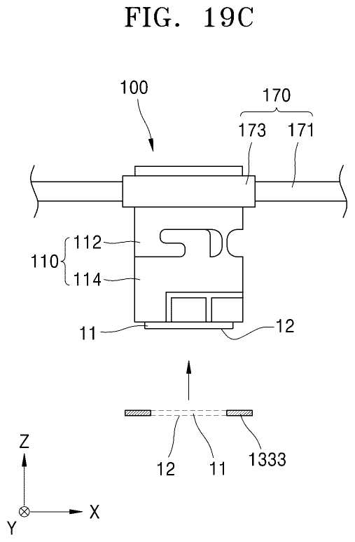

FIGS. 19A to 19C are conceptual diagrams illustrating a process of transporting a semiconductor chip by using a chip transport module 1330 of the bonding module 1300, according to an example embodiment.

Referring to FIGS. 15, 16, 19A, 19B, and 19C, after picking up the semiconductor chip 11 from the ring frame 40, the chip transport module 1330 may transport the semiconductor chip 11 from the chip separation stage 1320 to the bonding head 100 of a bonding stage 1340 along a sixth chip transfer path PA6 in FIG. 15, in operation S370.

As shown in FIG. 19A, a first gripper 1331 of the chip transport module 1330 may pick up the semiconductor chip 11 from the adhesive film 41 of the ring frame 40, thereby separating the semiconductor chip 11 from the adhesive film 41. The first gripper 1331 may be configured to support the semiconductor chip 11. To reduce or prevent the adhesive strength of the bonding surface 12 of the semiconductor chip 11 undergone plasma processing from decreasing, the first gripper 1331 may support the semiconductor chip 11 without contacting the bonding surface 12 of the semiconductor chip 11. For example, the first gripper 1331 may support an opposite surface to the bonding surface 12 of the semiconductor chip 11.

Subsequently, as shown in FIG. 19B, a second gripper 1333 may receive the semiconductor chip 11 from the first gripper 1331 and rotate such that the bonding surface 12 of the semiconductor chip 11 faces downwards. For example, the second gripper 1333 may rotate 180 degrees around the second horizontal direction (the Y direction) while supporting the semiconductor chip 11. To reduce or prevent the adhesive strength of the bonding surface 12 of the semiconductor chip 11 undergone plasma processing from decreasing, the second gripper 1333 may support the semiconductor chip 11 without contacting the bonding surface 12 of the semiconductor chip 11. For example, the second gripper 1333 may support the side surface of the semiconductor chip 11.

Subsequently, as shown in FIG. 19C, the bonding head 100 may receive the semiconductor chip 11 from the second gripper 1333 and vacuum-adsorb the semiconductor chip 11 in operation S380. When the semiconductor chip 11 is attached to the attachment pad 110, the opposite surface to the bonding surface 12 of the semiconductor chip 11 undergone plasma processing may be attached to the attachment pad 110.

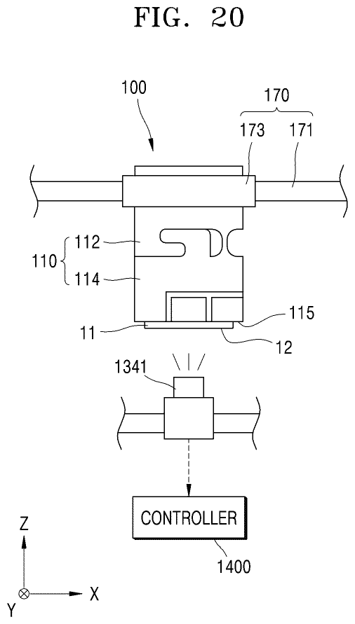

FIG. 20 is a conceptual diagram illustrating a process of detecting a position of the semiconductor chip 11, which has been attached to the bonding head 100, by using a first imaging device 1341, according to an example embodiment.

Referring to FIGS. 15, 16, and 20, a position of the semiconductor chip 11 attached to the bonding head 100 may be detected by using the first imaging device 1341 in operation S390.

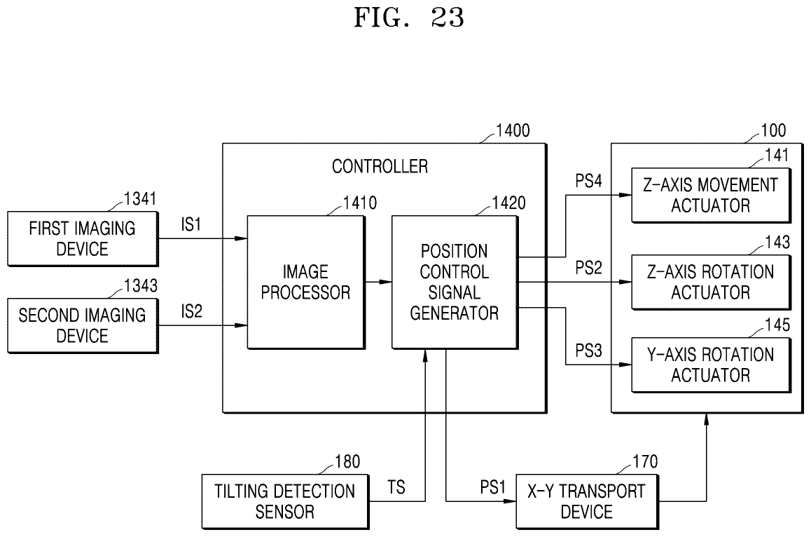

The first imaging device 1341 may include an image sensor. The first imaging device 1341 may transmit an image signal, which is obtained by capturing the semiconductor chip 11 attached to the attachment pad 110 of the bonding head 100, to a controller 1400. The controller 1400 may include an image processor 1410 (in FIG. 23), which may process an image signal obtained from the first imaging device 1341.

The controller 1400 may detect the position of the semiconductor chip 11, based on the image signal obtained from the first imaging device 1341. For example, the controller 1400 may detect a relative position of the semiconductor chip 11 with respect to a desired (or alternatively, preset) reference position. In some example embodiments, the controller 1400 may detect a relative position of the semiconductor chip 11 on an X-Y plane (hereinafter, referred to as an “X-Y relative position of the semiconductor chip 11”) and a relative position of the semiconductor chip 11 according to a rotation direction.

When the semiconductor chip 11 has been forcibly deformed and is captured in the deformed state by the first imaging device 1341, it is difficult to precisely detect the position of the semiconductor chip 11 because the surface of the semiconductor chip 11 is convexly deformed. Accordingly, while the semiconductor chip 11 attached to the attachment pad 110 is being captured by the first imaging device 1341, the bonding head 100 may maintain the bottom surface 115 of the attachment pad 110 to be in a flat state (e.g., the initial state of the attachment pad 110).

Referring back to FIGS. 15 and 16, a second carrier CA2 accommodating the substrate 21 may be loaded onto a second load port 1112 in operation S410. For example, the second carrier CA2 may include a FOUP. The substrate 21 may include a wafer including a plurality of chips.

Subsequently, the substrate 21 may be transferred from the second carrier CA2 to the plasma processing module 1120 and the plasma processing module 1120 may perform plasma processing on the substrate 21, in operation S420.

In operation S420, the substrate 21 may be transferred by the transfer robot 1210 of the EFEM 1200. For example, the transfer robot 1210 may carry out the substrate 21 from the second carrier CA2 and transfer the substrate 21 to the plasma processing module 1120 along a first substrate transfer path PB1 in FIG. 15. In operation S420, the plasma processing module 1120 may perform plasma processing on the bonding surface 22 of the substrate 21 such that the bonding surface 22 of the substrate 21 has a bonding force suitable for a bonding process.

Although it is illustrated in FIG. 15 that the substrate 21 and the ring frame 40 are plasma-treated by the same plasma processing module 1120, the substrate 21 and the ring frame 40 may be plasma-treated by different plasma processing modules from each other.

When the plasma processing is completely performed on the substrate 21, the substrate 21 may be transferred to the cleaning module 1130 and the cleaning module 1130 may perform a cleaning process on the substrate 21, in operation S430. In operation S430, the transfer robot 1210 may transfer the substrate 21 from the plasma processing module 1120 to the cleaning module 1130 along a second substrate transfer path PB2 in FIG. 15. In operation S430, the cleaning module 1130 may inject a cleaning solution to the substrate 21 to clean contaminants off the surface of the substrate 21.

Although it is illustrated in FIG. 15 that the substrate 21 and the ring frame 40 are cleaned by the same cleaning module 1130, the substrate 21 and the ring frame 140 may be cleaned by different cleaning modules from each other.

When the cleaning process is completely performed on the substrate 21, the substrate 21 may be transferred to a second aligner 1230 included in the EFEM 1200 and the second aligner 1230 may align the substrate 21 with a desired (or alternatively, preset) direction, in operation S440. In operation S440, the transfer robot 1210 may transfer the substrate 21 from the cleaning module 1130 to the second aligner 1230 along a third substrate transfer path PB3 in FIG. 15.

Thereafter, the substrate 21 may be transferred from the second aligner 1230 to a loading/unloading stage 1350 of a bonding module 1300 in operation S450. In operation S450, the transfer robot 1210 may transfer the substrate 21 from the second aligner 1230 to the loading/unloading stage 1350 of the bonding module 1300 along a fourth substrate transfer path PB4 in FIG. 15. The loading/unloading stage 1350 may include a transport member transporting the substrate 21.

Thereafter, the loading/unloading stage 1350 may transport the substrate 21 to the support 410 of the bonding stage 1340 in operation S460. The substrate 21 may be transferred from the loading/unloading stage 1350 to the bonding stage 1340 along a fifth substrate transfer path PB5 in FIG. 15 and mounted on the main surface 411 of the support 410. For example, the support 410 may include a chuck configured to support the substrate 21 by using vacuum or an electrostatic force.

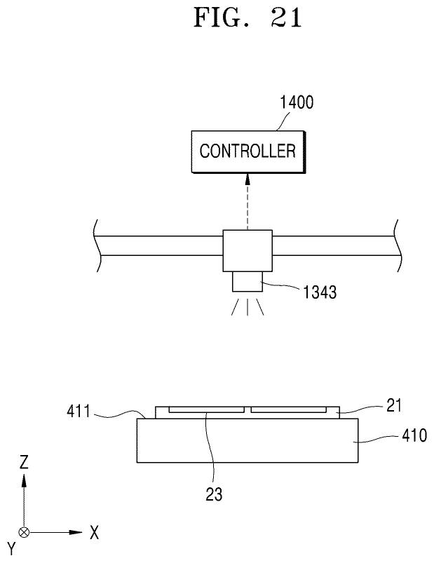

FIG. 21 is a conceptual diagram illustrating a process of detecting a position of the substrate 21 by using a second imaging device 1343, according to an example embodiment.

Referring to FIGS. 15, 16, and 21, the position of the substrate 21 mounted on the support 410 may be detected by using the second imaging device 1343 in operation S470.

The second imaging device 1343 may include an image sensor. The second imaging device 1343 may transmit an image signal, which is obtained by capturing the substrate 21 mounted on the support 410, to the controller 1400.

The controller 1400 may detect the position of the substrate 21 or the position of the chip 23 of the substrate 21, based on the image signal obtained from the second imaging device 1343. For example, the controller 1400 may detect a relative position of the substrate 21 with respect to a desired (or alternatively, preset) reference position. In some example embodiments, the controller 1400 may detect a relative position of the substrate 21 on an X-Y plane (hereinafter, referred to as an “X-Y relative position of the substrate 21”) and a relative position of the substrate 21 according to a rotation direction.

Referring to FIGS. 15 and 16, after the semiconductor chip 11 is transferred by the bonding head 100 to above the support 410 of the bonding stage 1340 such that the semiconductor chip 11 is aligned with a chip of the substrate 21, bonding between the semiconductor chip 11 and the substrate 21 may be performed in operation S500. The bonding head 100 may transfer the semiconductor chip 11 to a position, which is aligned with the chip of the substrate 21 mounted on the support 410, along a seventh chip transfer path PA7 in FIG. 15. The bonding stage 1340 may include a chip stacker which stacks the semiconductor chip 11 on the substrate 21. In operation S500, the bonding between the semiconductor chip 11 and the substrate 21 may be performed by using the chip-substrate bonding method described with reference to FIGS. 6A to 6J, the chip-substrate bonding method described with reference to FIGS. 10A to 10G, the chip-substrate bonding method described with reference to FIGS. 13A to 13E, or the chip-substrate bonding method described with reference to FIGS. 14A to 14C.

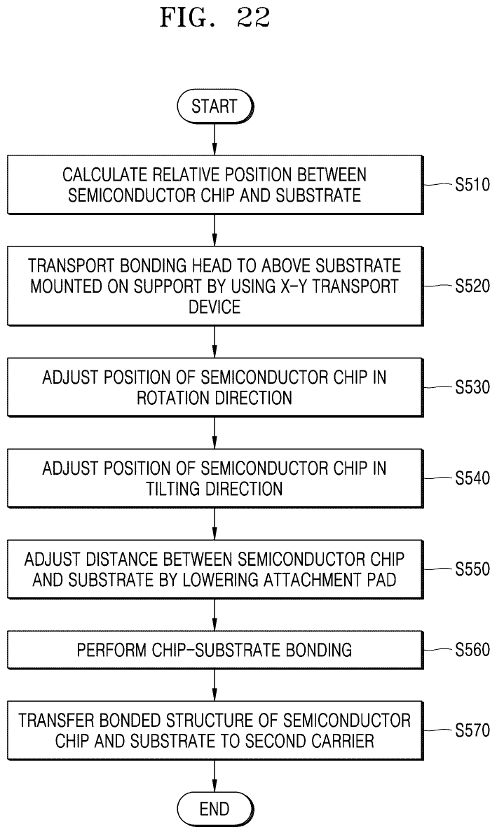

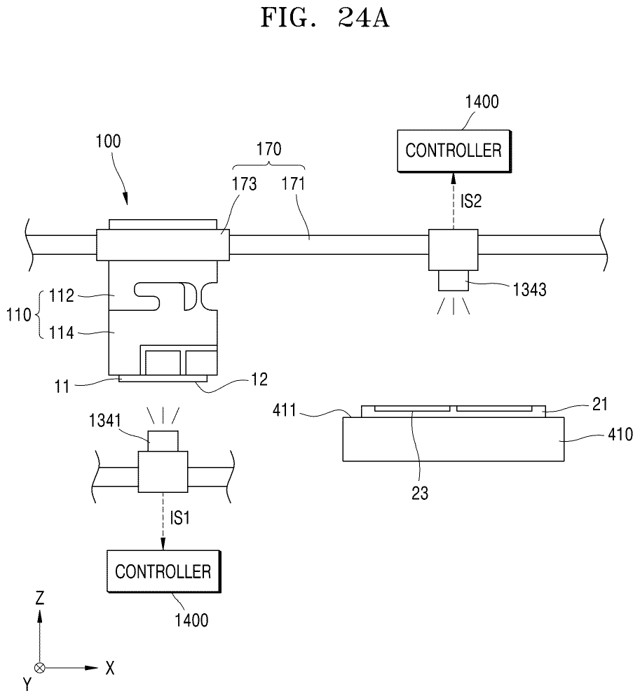

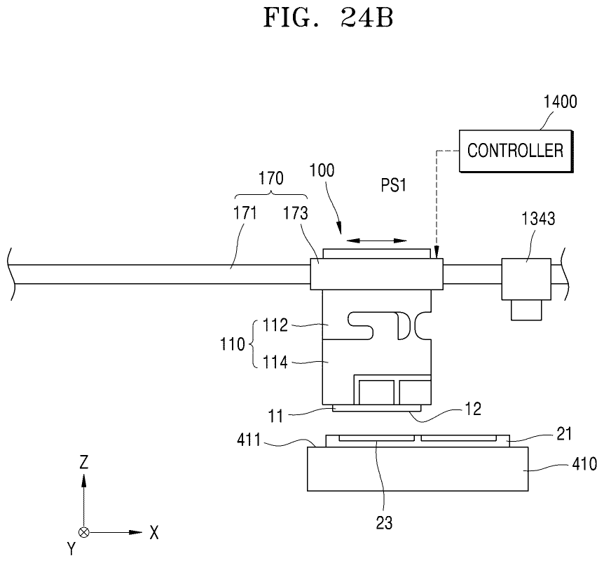

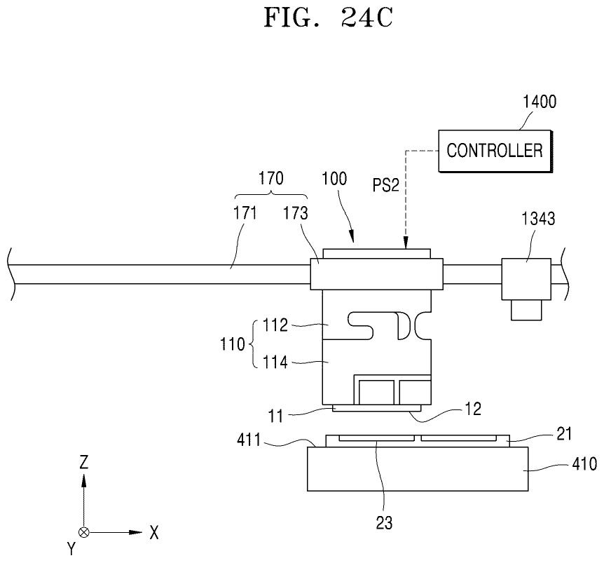

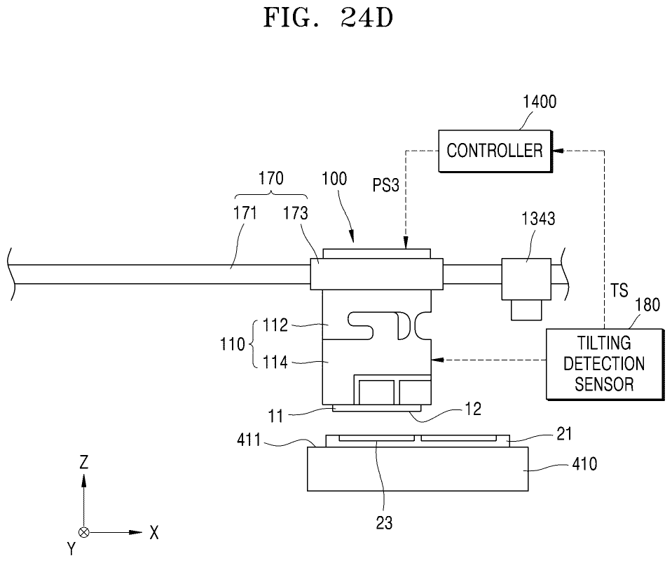

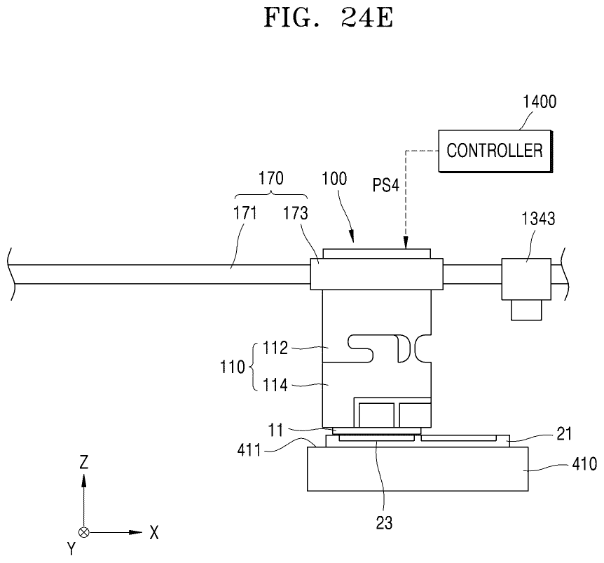

FIG. 22 is a flowchart of a chip-substrate bonding method using the semiconductor manufacturing apparatus 1 of FIG. 15, according to an example embodiment. FIG. 23 is a block diagram of a bonding module 1300 according to an example embodiment. FIGS. 24A to 24E are conceptual diagrams illustrating the chip-substrate bonding method using the semiconductor manufacturing apparatus 1 of FIG. 15.

Referring to FIGS. 22, 23, and 24A, a relative position between the semiconductor chip 11 and the substrate 21 may be calculated in operation S510.

In some example embodiments, the image processor 1410 of the controller 1400 may process an image signal IS1 transmitted from the first imaging device 1341 and an image signal IS2 transmitted from the second imaging device 1343 and may calculate the relative position between the semiconductor chip 11 and the substrate 21. For example, the image processor 1410 of the controller 1400 may calculate the relative position between the semiconductor chip 11 and the chip 23 of the substrate 21, wherein the chip 23 of the substrate 21 is bonded to the semiconductor chip 11. Here, the relative position between the semiconductor chip 11 and the substrate 21 may include a relative position in the first horizontal direction (the X direction), a relative position in the second horizontal direction (the Y direction), and/or a relative position in the rotation direction.

Based on information about the calculated relative position between the semiconductor chip 11 and the substrate 21, the controller 1400 may determine a target position at which the semiconductor chip 11 is aligned with the chip 23 of the substrate 21. Here, the target position may refer to a position at which the semiconductor chip 11 is aligned with the chip 23 of the substrate 21 in the first horizontal direction (the X direction), the second horizontal direction (the Y direction), and the rotation direction. In other words, the controller 1400 may determine a target position (hereinafter, referred to as a “target X-Y position”), at which the semiconductor chip 11 is aligned with the chip 23 of the substrate 21 on an X-Y plane, and a target position (hereinafter, referred to as a “target rotation position”), at which the semiconductor chip 11 is aligned with the chip 23 of the substrate 21 in the rotation direction.

A position control signal generator 1420 of the controller 1400 may generate a position control signal for transferring the semiconductor chip 11 to the target position, based on the signal transmitted from the image processor 1410. The position control signal generator 1420 may generate a first position signal PS1 for positioning the semiconductor chip 11 at the target X-Y position and a second position signal PS2 for positioning the semiconductor chip 11 at the target rotation position.

The position control signal generator 1420 may include at least one processor configured to perform certain operation and algorithm. For example, the at least one processor may include a microprocessor, a CPU, and/or the like.

Referring to FIGS. 22, 23, and 24B, the bonding head 100 may be transported to above the substrate 21 mounted on the support 410, by using an X-Y transport device 170, in operation S520.

For example, the X-Y transport device 170 may be implemented by a gantry system or a linear movement module that is configured to linearly move the bonding head 100. For example, the X-Y transport device 170 may include a moving rail 171, which extends in the first horizontal direction (the X direction) and/or the second horizontal direction (the Y direction), and a moving block 173, which is coupled to the bonding head 100 and configured to move along the moving rail 171. The moving block 173 may be connected to an actuator and may linearly move along the moving rail 171 by the actuator. The bonding head 100 may be moved on an X-Y plane by the linear movement of the moving block 173.

The position control signal generator 1420 may apply, to the X-Y transport device 170, the first position signal PS1 for transporting the semiconductor chip 11 to the target X-Y position, in operation S520. The X-Y transport device 170 may move the bonding head 100 based on the first position signal PS1, thereby positioning the semiconductor chip 11 at the target X-Y position.

Referring to FIGS. 22, 23, and 24C, the bonding head 100 may adjust the position of the semiconductor chip 11 in the rotation direction by using the Z-axis rotation actuator 143 in operation S530.

In operation S530, the position control signal generator 1420 may apply, to the Z-axis rotation actuator 143, the second position signal PS2 for positioning semiconductor chip 11 at the target rotation position. The Z-axis rotation actuator 143 may position the semiconductor chip 11 at the target rotation position by rotating the attachment pad 110 around a direction perpendicular to the main surface 411 of the support 410, based on the second position signal PS2.

Referring to FIGS. 22, 23, and 24D, the bonding head 100 may adjust the position of the semiconductor chip 11 in a tilting direction by using the Y-axis rotation actuator 145 in operation S540.

In operation S540, a tilting detection sensor 180 may be configured to detect the position of the semiconductor chip 11 in the tilting direction. For example, the tilting detection sensor 180 may be configured to detect a position of the attachment pad 110 or a structure, to which the attachment pad 110 is coupled, in the tilting direction. The position of the semiconductor chip 11 in the tilting direction may be detected by using the position of the attachment pad 110 in the tilting direction, which is detected by the tilting detection sensor 180.

In operation S540, the controller 1400 may determine a target position (hereinafter, referred to as a “target tilting position”) of the semiconductor chip 11 in the tilting direction, based on a detection signal TS corresponding to the position, detected by the tilting detection sensor 180, of the semiconductor chip 11 in the tilting direction.

The position control signal generator 1420 may generate a third position signal PS3 for positioning the semiconductor chip 11 at the target tilting position and apply the third position signal PS3 to the Y-axis rotation actuator 145. The Y-axis rotation actuator 145 may tilt the attachment pad 110 around a direction (e.g., the X direction or the Y direction), which is parallel with the main surface 411 of the support 410, based on the third position signal PS3 and thus position the semiconductor chip 11 at the target tilting position.

In some example embodiments, the target tilting position may be a position at which the bonding surface 12 of the semiconductor chip 11 is parallel with the bonding surface 22 of the substrate 21. Alternatively, as shown in FIGS. 5 to 17, when the bonding between the semiconductor chip 11 and the substrate 21 progresses in a direction from the first edge of the semiconductor chip 11 toward the second edge of the semiconductor chip 11, the target tilting position may be a position at which the bonding surface 12 of the semiconductor chip 11 is inclined at a desired (or alternatively, preset) angle with respect to the bonding surface 22 of the substrate 21.

Referring to FIGS. 22, 23, and 24E, the Z-axis movement actuator 141 of the bonding head 100 may lower the attachment pad 110 such that the semiconductor chip 11 is spaced apart from the substrate 21 by a desired (or alternatively, preset) distance, in operation S550. For example, the Z-axis movement actuator 141 may adjust the position of the attachment pad 110 in the vertical direction (Z direction) according to a fourth position signal PS4 received from the controller 1400.

In some example embodiments, operation S530, in which the position of the semiconductor chip 11 is adjusted in the rotation direction, and/or operation S540, in which the position of the semiconductor chip 11 is adjusted in the tilting direction, may be performed while the attachment pad 110 is being lowered such that the semiconductor chip 11 is spaced apart from the substrate 21 by the desired (or alternatively, preset) distance in operation S550.

Referring to FIGS. 22 and 23, when the semiconductor chip 11 is positioned such that the semiconductor chip 11 is spaced apart from the substrate 21 by the desired (or alternatively, preset) distance, bonding between the semiconductor chip 11 and the substrate 21 may be performed in operation S560. In operation S560, the bonding between the semiconductor chip 11 and the substrate 21 may be performed by using the chip-substrate bonding method described with reference to FIGS. 6A to 6J, the chip-substrate bonding method described with reference to FIGS. 10A to 10G, the chip-substrate bonding method described with reference to FIGS. 13A to 13E, or the chip-substrate bonding method described with reference to FIGS. 14A to 14C.

When the bonding between the semiconductor chip 11 and the substrate 21 is completed, a bonded structure, in which the semiconductor chip 11 is bonded to the substrate 21, may be transferred to the loading/unloading stage 1350 along a first transfer path PC1 in FIG. 15, and the transfer robot 1210 of the EFEM 1200 may transfer the bonded structure to the second carrier CA2 along a second transfer path PC2, in operation S570.

According to some example embodiments, bonding alignment between the semiconductor chip 11 and the substrate 21 may be increased by adjusting the X-Y position of the semiconductor chip 11, the position of the semiconductor chip 11 in the Z-axis rotation direction, and the position of the semiconductor chip 11 in the Y-axis rotation direction. Accordingly, reliability of the bonded structure of the semiconductor chip 11 and the substrate 21 and/or reliability of semiconductor products manufactured using the bonded structure may be increased.

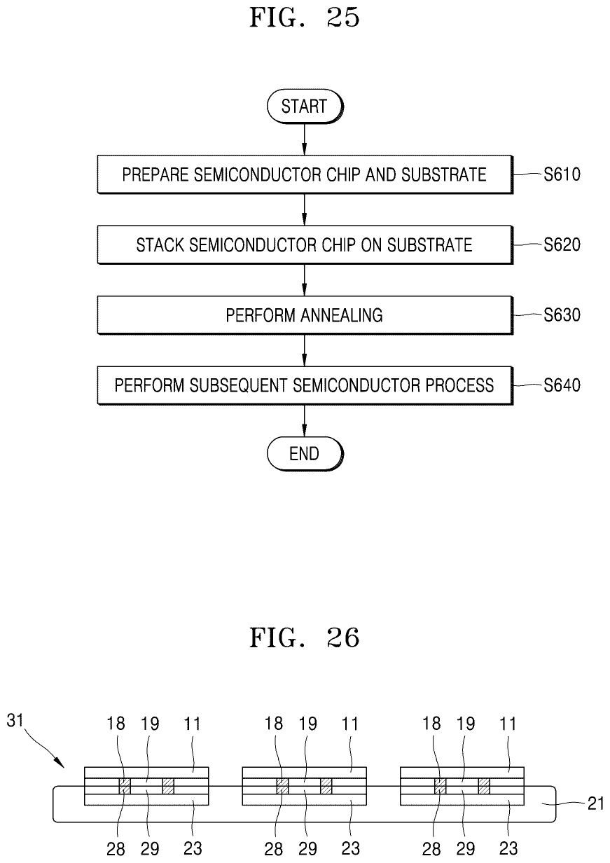

FIG. 25 is a flowchart of a semiconductor manufacturing method according to an example embodiment. FIG. 26 is a cross-sectional view of a bonded structure 31 in which the semiconductor chip 11 is bonded to the substrate 21.

Referring to FIGS. 25 and 26, the semiconductor chip 11 and the substrate 21, which are bonding targets, may be prepared in operation S610. The substrate 21 may include a wafer in which a plurality of chips 23 are formed.

The semiconductor chip 11 may include a first insulating layer 19 and a first conductive pattern 18. Each of the chips 23 of the substrate 21 may include a second insulating layer 29 and a second conductive pattern 28. For example, the first insulating layer 19 and the second insulating layer 29 may include silicon oxide. For example, the first conductive pattern 18 and the second conductive pattern 28 may include copper (Cu).

The semiconductor chip 11 and the chips of the substrate 21 each may include a plurality of individual devices and a wiring structure electrically connecting the individual devices to each other. The individual devices may include various microelectronic devices, e.g., a metal-oxide-semiconductor field effect transistor (MOSFET), a system large scale integration (LSI), an image sensor such as a complementary metal-oxide-semiconductor (CMOS) image sensor (CIS), a micro-electro-mechanical system (MEMS), an active element, and a passive element. In some example embodiments, each of the chips 23 of the substrate 21 may correspond to a logic chip, and the semiconductor chip 11 may correspond to a memory chip. In some example embodiments, each of the chips 23 of the substrate 21 may correspond to a logic chip, and the semiconductor chip 11 may correspond to an image sensor chip.

Subsequently, the semiconductor chip 11 may be stacked on the substrate 21 in operation S620. The semiconductor chip 11 may be aligned with and bonded to one of the chips 23 of the substrate 21. A surface of the semiconductor chip 11 may contact a surface of the substrate 21, and the first conductive pattern 18 of the semiconductor chip 11 may contact the second conductive pattern 28 of the substrate 21. Although it is illustrated in FIG. 26 that one semiconductor chip 11 is stacked on the chip 23 of the substrate 21, at least two semiconductor chips may be vertically stacked on the chip 23 of the substrate 21.

Subsequently, when the semiconductor chip 11 is completely stacked on the substrate 21, annealing may be performed on the bonded structure 31, in which the semiconductor chip 11 is bonded to the substrate 21, to increase the bonding strength between the semiconductor chip 11 and the substrate 21 in operation S630. Through the annealing, the first conductive pattern 18 of the semiconductor chip 11 may be more firmly bonded to the second conductive pattern 28 of the substrate 21 and the first insulating layer 19 of the semiconductor chip 11 may be more firmly bonded to the second insulating layer 29 of the substrate 21.

Subsequently, a subsequent semiconductor process may be performed on the bonded structure 31 in operation S640. The subsequent semiconductor process may include various processes. For example, the subsequent semiconductor process may include a vapor deposition process, an etching process, an ion process, a cleaning process, and the like. Here, the vapor deposition process may include various material-layer forming processes, such as chemical vapor deposition (CVD), sputtering, and spin coating. The ion process may include ion implantation, diffusion, and heat treatment. The subsequent semiconductor process may also include a packaging process, in which a semiconductor device is mounted on a printed circuit board and a molding layer is formed. The subsequent semiconductor process may also include a test process, in which a semiconductor device or a semiconductor package is tested. A semiconductor device or a semiconductor package may be completely formed by performing the subsequent semiconductor process.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A semiconductor manufacturing apparatus configured to bond a semiconductor chip to a substrate, the semiconductor manufacturing apparatus comprising:
a bonding head configured to transfer the semiconductor chip such that the semiconductor chip is stacked on the substrate, the bonding head including
an attachment pad configured to attach the semiconductor chip thereto, and
a vertical movement actuator configured to lower the attachment pad such that a portion of an edge of the semiconductor chip comes into contact with a top surface of the substrate,
wherein the attachment pad is configured to rotate around an axis that passes through the portion of the edge of the semiconductor chip in contact with the substrate.

2. The semiconductor manufacturing apparatus of claim 1, wherein
the attachment pad includes:
an upper body having a groove; and
a lower body configured to attach the semiconductor chip thereto, the lower body including a stopper, the stopper configured to be inserted into the groove.

3. The semiconductor manufacturing apparatus of claim 2, wherein
the attachment pad further includes an elastic hinge connecting the upper body and the lower body to each other,
wherein a thickness of the elastic hinge is configured to vary with the rotation of the attachment pad.

4. The semiconductor manufacturing apparatus of claim 2, wherein,
when the attachment pad rotates, an angle by which the upper body rotates is different from an angle by which the lower body rotates.

5. The semiconductor manufacturing apparatus of claim 2, wherein
before the semiconductor chip contacts the substrate, the stopper is spaced apart from the upper body, in the groove, and
a distance by which the stopper is spaced apart from the upper body is 10 μm to 99 μm.

6. The semiconductor manufacturing apparatus of claim 1, wherein
the attachment pad includes a vacuum passage extending from a bottom surface thereof to which the semiconductor chip is attached, and
the semiconductor manufacturing apparatus further comprises a vacuum pump that is connected to the vacuum passage and configured to apply vacuum pressure to the vacuum passage.

7. The semiconductor manufacturing apparatus of claim 1, wherein
the attachment pad is configured to rotate around the axis that passes through the portion of the edge of the semiconductor chip in contact with the substrate, until a bottom surface of the semiconductor chip attached to the attachment pad contacts an entirety of the top surface of the substrate.

8. The semiconductor manufacturing apparatus of claim 1, wherein
the attachment pad includes:
an upper body including a first groove and a second groove;
a middle body including a third groove, a first stopper configured to be inserted into the first groove, and a second stopper configured to be inserted into the second groove; and
a lower body including a third stopper configured to be inserted into the third groove, the lower body configured to attach the semiconductor chip thereto.

9. The semiconductor manufacturing apparatus of claim 8, wherein
the upper body, the middle body, and the lower body being a single integral body, and,
when the attachment pad rotates, an angle by which the upper body rotates, an angle by which the middle body rotates, and an angle by which the lower body rotates are different from one another.

10. The semiconductor manufacturing apparatus of claim 1, wherein
a bottom surface of the attachment pad has a convex shape, and
a maximum height difference in the bottom surface of the attachment pad is 5 μm to 30 μm.

11. The semiconductor manufacturing apparatus of claim 1, wherein
the bonding head further includes a parallel rotation actuator configured to rotate the attachment pad around an axis parallel with the top surface of the substrate,
the parallel rotation actuator is configured to rotate the attachment pad before the semiconductor chip comes into contact with the substrate.

12. A semiconductor manufacturing apparatus configured to bond a semiconductor chip to a substrate, the semiconductor manufacturing apparatus comprising:
a bonding head configured to transfer the semiconductor chip such that the semiconductor chip is stacked on the substrate, the bonding head including an attachment pad configured to attach the semiconductor chip thereto,
wherein the attachment pad includes
a lower body configured to attach the semiconductor chip thereto,
an upper body including a space configured to accommodate the lower body, and
a parallel rotation actuator in the space and connected to the lower body and the upper body, the parallel rotation actuator configured to rotate the lower body with respect to the upper body, which is stationary, by changing a length of the parallel rotation actuator in a lateral direction.

13. The semiconductor manufacturing apparatus of claim 12, wherein
the bonding head further includes a vertical movement actuator, the vertical movement actuator configured to lower the attachment pad such that a portion of an edge of the semiconductor chip comes into contact with a top surface of the substrate, and
the lower body is configured to rotate around an axis passing through the portion of the edge of the semiconductor chip in contact with the substrate.

14. The semiconductor manufacturing apparatus of claim 12, wherein,
when a portion of an edge of the semiconductor chip comes into contact with a top surface of the substrate,
the parallel rotation actuator is configured to, by reducing the length of the parallel rotation actuator in the lateral direction, rotate the lower body until a bottom surface of the semiconductor chip attached to the lower body contacts an entirety of the top surface of the substrate.

15. The semiconductor manufacturing apparatus of claim 12, wherein,
when a portion of an edge of the semiconductor chip comes into contact with a top surface of the substrate,
the parallel rotation actuator is configured to, by increasing the length of the parallel rotation actuator in the lateral direction, rotate the lower body until a bottom surface of the semiconductor chip attached to the lower body contacts an entirety of the top surface of the substrate.

16. The semiconductor manufacturing apparatus of claim 12, wherein
the attachment pad further includes an elastic connector configured to connect the upper body to the lower body, wherein a length of the elastic connector is configured to change when the lower body rotates.

17. The semiconductor manufacturing apparatus of claim 12, wherein
the lower body includes a step portion at a lower portion thereof, the step portion configured to attach the semiconductor chip thereto,
the attachment pad further includes a vacuum passage extending from the step portion of the lower body, and
the semiconductor manufacturing apparatus further comprises a vacuum pump connected to the vacuum passage and configured to apply vacuum pressure to the vacuum passage.

18. The semiconductor manufacturing apparatus of claim 12, wherein
before the semiconductor chip contacts the substrate, the upper body is spaced apart from the lower body, and
a distance by which the upper body is spaced apart from the lower body is 10 μm to 99 μm.

19. A semiconductor manufacturing apparatus comprising:
a loading stage configured to load a ring frame having a semiconductor chip mounted thereon;
a loading/unloading stage configured to load a substrate thereon and unload the substrate therefrom;
a chip separation stage configured to reducing adhesive strength of an adhesive film of the ring frame supporting the semiconductor chip;
a bonding stage configured to perform a bonding process on the substrate and the semiconductor chip, the bonding stage including a support and a bonding head, the support including a main surface on which the substrate is to be mounted, the bonding head configured to stack the semiconductor chip on the substrate mounted on the support; and
a chip transport module configured to transport the semiconductor chip from the chip separation stage toward the bonding head,
wherein the bonding head includes
an attachment pad configured to attach the semiconductor chip thereto, and
a vertical movement actuator configured to lower the attachment pad such that a portion of an edge of the semiconductor chip comes into contact with a top surface of the substrate, and
wherein the attachment pad is configured to rotate around an axis passing through the portion of the edge of the semiconductor chip in contact with the substrate until a bottom surface of the semiconductor chip attached to the attachment pad contacts an entirety of the top surface of the substrate.

20. The semiconductor manufacturing apparatus of claim 19, wherein
the attachment pad includes:
an upper body including a groove; and
a lower body including a stopper, the stopper configured to be inserted into the groove and contact the upper body when the bottom surface of the semiconductor chip contacts an entirety of the top surface of the substrate.
